(19) United States
(12) Patent Application Publication
(10) Pub. No.: US 2024/0120387 A1
(43) Pub. Date: Apr. 11, 2024

(54) NITRIDE SEMICONDUCTOR DEVICE

(71) Applicant: ROHM CO., LTD., Kyoto-shi (JP)

(72) Inventor: Hirotaka OTAKE, Kyoto-shi (JP)

(73) Assignee: ROHM CO., LTD., Kyoto-shi (JP)

(21) Appl. No.: 18/542,798

(22) Filed: Dec. 18, 2023

Related U.S. Application Data
(63) Continuation of application No. PCT/JP2022/025617, filed on Jun. 27, 2022.

(30) Foreign Application Priority Data
Jul. 1, 2021 (JP) 2021-110131

(51) Int. Cl. H01L 29/20; H01L 29/40; H01L 29/778

(52) U.S. Cl. CPC H01L 29/2003; H01L 29/402; H01L 29/7787

(57) ABSTRACT

A nitride semiconductor device includes a passivation layer which has a first opening and a second opening, and which covers an electron supply layer, a gate layer, and a gate electrode. The passivation layer includes: a first insulation layer formed on at least a portion of the electron supply layer positioned, in plan view, between the first opening and gate layer; and a second insulation layer which covers the gate layer and gate electrode, and which is formed on the electron supply layer positioned, in plan view, between the second opening and gate layer. The second insulation layer is formed from a material having a Young's modulus lower than that of the first insulation layer.

### CROSS-REFERENCE TO RELATED APPLICATIONS

The present application is a bypass continuation of International Patent Application No. PCT/JP2022/025617, filed on Jun. 27, 2022, which corresponds to Japanese Patent Application No. 2021-110131 filed on Jul. 1, 2021 with the Japan Patent Office, and the entire disclosure of these applications are incorporated herein by reference.

### BACKGROUND

### 1. Field

The present disclosure relates to a nitride semiconductor device.

### 2. Description of Related Art

A nitride semiconductor is currently used to produce a high-electron-mobility transistor (HEMT). When an HEMT is used in a power device, from the viewpoint of being fail-safe, the HEMT is required to be normally off so that the source-drain current path (channel) is disconnected in a zero bias state. Japanese Laid-Open Patent Publication No. 2017-73506 discloses a nitride semiconductor HEMT of a normally-off type.

The HEMT disclosed in Japanese Laid-Open Patent Publication No. 2017-73506 includes an electron transit layer composed of a gallium nitride (GaN) layer and an electron supply layer composed of an aluminum gallium nitride (AlGaN) layer. In the electron transit layer, a two-dimensional electron gas (2DEG) is generated in the vicinity of a heterojunction interface between the electron transit layer and the electron supply layer and forms a channel of the HEMT. Japanese Laid-Open Patent Publication No. 2017-73506 discloses that a GaN layer (p-type GaN layer) including an acceptor impurity is arranged under a gate electrode to interrupt the channel formed from 2DEG so that a normally-off operation is achieved.

### BRIEF DESCRIPTION OF THE DRAWINGS

FIG. 1 is a schematic cross-sectional view showing an exemplary nitride semiconductor device of a first embodiment.

FIG. 2 is a schematic plan view showing an exemplary pattern formed in the nitride semiconductor device shown in FIG. 1.

FIG. 3 is a schematic cross-sectional view showing an exemplary step for manufacturing the nitride semiconductor device shown in FIG. 1.

FIG. 4 is a schematic cross-sectional view showing a manufacturing step subsequent to FIG. 3.

FIG. 5 is a schematic cross-sectional view showing a manufacturing step subsequent to FIG. 4.

FIG. 6 is a schematic cross-sectional view showing a manufacturing step subsequent to FIG. 5.

FIG. 7 is a schematic cross-sectional view showing a manufacturing step subsequent to FIG. 6.

FIG. 8 is a schematic cross-sectional view showing a manufacturing step subsequent to FIG. 7.

FIG. 9 is a schematic cross-sectional view showing a manufacturing step subsequent to FIG. 8.

FIG. 10 is a schematic cross-sectional view showing a manufacturing step subsequent to FIG. 9.

FIG. 11 is a schematic cross-sectional view showing a manufacturing step subsequent to FIG. 10.

FIG. 12 is a schematic cross-sectional view showing a manufacturing step subsequent to FIG. 11.

FIG. 13 is a schematic cross-sectional view showing an exemplary nitride semiconductor device in a first modified example of the first embodiment.

FIG. 14 is a schematic cross-sectional view showing an exemplary nitride semiconductor device in a second modified example of the first embodiment.

FIG. 15 is a schematic cross-sectional view showing an exemplary nitride semiconductor device in a third modified example of the first embodiment.

FIG. 16 is a schematic cross-sectional view showing an exemplary nitride semiconductor device of a second embodiment.

FIG. 17 is a schematic cross-sectional view showing an exemplary step for manufacturing the nitride semiconductor device shown in FIG. 16.

FIG. 18 is a schematic cross-sectional view showing a manufacturing step subsequent to FIG. 17.

FIG. 19 is a schematic cross-sectional view showing a manufacturing step subsequent to FIG. 18.

### DETAILED DESCRIPTION

Embodiments of a nitride semiconductor device according to the present disclosure will be described below with reference to the drawings. In the drawings, elements may not be drawn to scale for simplicity and clarity of illustration. In a cross-sectional view, hatching may be omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

### First Embodiment

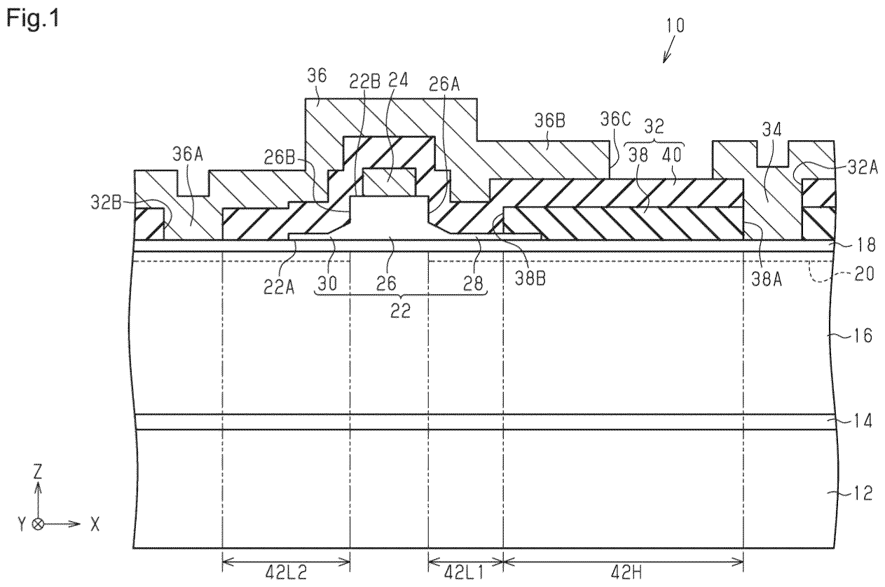

FIG. 1 is a schematic cross-sectional view showing an exemplary nitride semiconductor device 10 of a first embodiment. The nitride semiconductor device 10 may be, for example, a high-electron-mobility transistor (HEMT) that uses gallium nitride (GaN). The nitride semiconductor device 10 includes a substrate 12, a buffer layer 14 formed on the substrate 12, an electron transit layer 16 formed on the buffer layer 14, and an electron supply layer 18 formed on the electron transit layer 16.

The substrate 12 may be formed of silicon (Si), silicon carbide (SiC), GaN, sapphire, or other substrate materials. In an example, the substrate 12 is a Si substrate. The thickness of the substrate 12 may be, for example, in a range of 200 μm to 1500 μm. Among XYZ-axes that are orthogonal to each other shown in FIG. 1, the Z-direction is a direction orthogonal to a surface of the substrate 12 on which a device is formed. The term “plan view” used in this specification refers to a view of the nitride semiconductor device 10 in the Z-direction from above unless otherwise specifically described.

The buffer layer 14 may be disposed between the substrate 12 and the electron transit layer 16 and may be formed of any material that reduces the lattice mismatching between the substrate 12 and the electron transit layer 16. The buffer layer 14 may include one or more nitride semiconductor layers and, for example, at least one of an aluminum nitride (AlN) layer, an aluminum gallium nitride (AlGaN) layer, and a graded AlGaN layer including different aluminum (Al) compositions. For example, the buffer layer 14 may include a single AlN layer, a single AlGaN layer, a layer having a superlattice structure of AlGaN/GaN, a layer having a superlattice structure of AlN/AlGaN, or a layer having a superlattice structure of AlN/GaN.

In an example, the buffer layer 14 may include a first buffer layer that is an AlN layer formed on the substrate 12 and a second buffer layer that is an AlGaN layer formed on the AlN layer. In an example, the first buffer layer may be an AlN layer having a thickness of 200 nm. In an example, the second buffer layer may have a structure in which AlGaN layers having a thickness of 100 nm are stacked. To inhibit current leakage of the buffer layer 14, a portion of the buffer layer 14 may be doped with an impurity so that the buffer layer 14 becomes semi-insulating. In this case, the impurity is, for example, carbon (C) or iron (Fe). The concentration of the impurity may be, for example, greater than or equal to 4×10¹⁶ cm⁻³.

The electron transit layer 16 is composed of a nitride semiconductor and may be, for example, a GaN layer. The electron transit layer 16 may have a thickness, for example, in a range of 0.5 μm to 2 μm. To inhibit current leakage from the electron transit layer 16, a portion of the electron transit layer 16 may be doped with an impurity so that the electron transit layer 16 excluding an outer layer region is semi-insulating. In this case, the impurity is, for example, C. The concentration of the impurity may be, for example, greater than or equal to 1×10¹⁹ cm⁻³ at a peak concentration. More specifically, the electron transit layer 16 may include GaN layers having different impurity concentrations, for example, a C-doped GaN layer and a non-doped GaN layer. In this case, the C-doped GaN layer may be formed on the buffer layer 14 and have a thickness in a range of 0.3 μm to 2 μm. The C concentration in the C-doped GaN layer may be in a range of 9×10¹⁸ cm⁻³ to 9×10¹⁹ cm⁻³. The non-doped GaN layer may be formed on the C-doped GaN layer and have a thickness in a range of 0.05 μm to 0.3 μm. The non-doped GaN layer is in contact with the electron supply layer 18. In an example, the electron transit layer 16 includes a non-doped GaN layer having a thickness of 0.3 μm and a C-doped GaN layer having a thickness of 0.4 μm. The concentration of C in the C-doped GaN layer is approximately 5×10¹⁹ cm⁻³.

The electron supply layer 18 is composed of a nitride semiconductor having a band gap that is larger than that of the electron transit layer 16 and may be, for example, an AlGaN layer. The band gap increases as the Al composition increases. Therefore, the electron supply layer 18, which is an AlGaN layer, has a larger band gap than the electron transit layer 16, which is a GaN layer. In an example, the electron supply layer 18 is formed from AlₓGa₁₋ₓN, where 0.1<x<0.4, and more preferably, 0.2<x<0.3. The electron supply layer 18 may have a thickness in a range of 5 nm to 20 nm. In an example, the thickness of the electron supply layer 18 is greater than or equal to 8 nm. More specifically, the thickness of the electron supply layer 18 may differ between a region of in the electron supply layer 18 immediately under the gate layer 22 and the remaining region. More specifically, in the region of the electron supply layer 18 excluding the region immediately under the gate layer 22, the thickness may be less than in the region immediately below the gate layer 22 as a result of over-etching when removing the p-type GaN layer composing the gate layer 22. In an example, the thickness of the electron supply layer 18 is greater than or equal to 10 nm in the region immediately under the gate layer 22. The region of the electron supply layer 18 excluding the region immediately under the gate layer 22 includes a region where the thickness of the electron supply layer 18 is 8 nm.

The electron transit layer 16 and the electron supply layer 18 are composed of nitride semiconductors having different lattice constants. Thus, the nitride semiconductor forming the electron transit layer 16 (e.g., GaN) and the nitride semiconductor forming the electron supply layer 18 (e.g., AlGaN) form a lattice-mismatching junction. In the vicinity of the heterojunction interface between the electron transit layer 16 and the electron supply layer 18, the energy level in the conduction band of the electron transit layer 16 is lower than the Fermi level due to spontaneous polarization of the electron transit layer 16 and the electron supply layer 18 and piezoelectric polarization caused by stress received by the heterojunction of the electron supply layer 18. As a result, at a location close to the heterojunction interface between the electron transit layer 16 and the electron supply layer 18 (for example, approximately a few nanometers away from the interface), two-dimensional electron gas 20 (2DEG) spreads in the electron transit layer 16. The sheet carrier density of the 2DEG formed in the electron transit layer 16 may be increased by increasing at least one of the Al composition and the thickness of the electron supply layer 18.

The nitride semiconductor device 10 further includes the gate layer 22 formed on the electron supply layer 18, a gate electrode 24 formed on the gate layer 22, a passivation layer 32 covering the electron supply layer 18, the gate layer 22, and the gate electrode 24 and including a first opening 32A and a second opening 32B, a drain electrode 34 in contact with the electron supply layer 18 through the first opening 32A, and a source electrode 36 in contact with the electron supply layer 18 through the second opening 32B.

The gate layer 22 is formed on a portion of the electron supply layer 18 and composed of a nitride semiconductor including an acceptor impurity. The gate layer 22 may be formed of any material having a band gap that is smaller than that of the electron supply layer 18, which is, for example, an AlGaN layer. In an example, the gate layer 22 is a GaN layer (p-type GaN layer) doped with an acceptor impurity. The acceptor impurity may include at least one of zinc (Zn), magnesium (Mg), and carbon (C). The maximum concentration of the acceptor impurity in the gate layer 22 is, for example, in a range of 7×10¹⁸ cm⁻³ to 1×10²⁰ cm⁻³.

The gate layer 22 includes a bottom surface 22A in contact with the electron supply layer 18 and an upper surface 22B opposite to the bottom surface 22A. The gate electrode 24 is formed on the upper surface 22B of the gate layer 22. In the ZX-plane shown in FIG. 1, the gate layer 22 may have a cross section that is rectangular, trapezoidal, or ridged.

In the example shown in FIG. 1, the gate layer 22 includes a ridge 26 including the upper surface 22B, on which the gate electrode 24 is formed, and a first extension 28 and a second extension 30 extending outward from the ridge 26 in plan view.

The ridge 26 includes a first ridge end 26A and a second ridge end 26B. The first ridge end 26A is an end of the ridge 26 located closer to the first opening 32A. The second ridge end 26B is an end of the ridge 26 located closer to the second opening 32B.

In plan view, the first extension 28 extends from the ridge 26 toward the first opening 32A. The first extension 28 abuts the first ridge end 26A. In other words, in plan view, the first extension 28 extends from the first ridge end 26A toward the first opening 32A. The first extension 28 is separated from the first opening 32A.

In plan view, the second extension 30 extends from the ridge 26 toward the second opening 32B. The second extension 30 abuts the second ridge end 26B. In other words, in plan view, the second extension 30 extends from the second ridge end 26B toward the second opening 32B. The second extension 30 is separated from the second opening 32B.

The ridge 26 is located between the first extension 28 and the second extension 30 and formed integrally with the first extension 28 and the second extension 30. Since the gate layer 22 includes the first extension 28 and the second extension 30, the bottom surface 22A may be greater in area than the upper surface 22B.

The ridge 26 corresponds to a relatively thick portion of the gate layer 22 and may have a thickness in a range of 80 nm to 150 nm. The thickness of the gate layer 22 may be determined taking into consideration parameters including a gate threshold voltage. In an example, the thickness of the gate layer 22 is greater than 100 nm.

The first extension 28 and the second extension 30 are smaller in thickness than the ridge 26. Each of the first extension 28 and the second extension 30 may have different thicknesses depending on the position. In the example shown in FIG. 1, each of the first extension 28 and the second extension 30 includes a tapered portion having a thickness that gradually decreases as the ridge 26 becomes farther in a region abutting on the ridge 26 and a flat portion having a substantially constant thickness in a region separated from the ridge 26 by a predetermined distance. Alternatively, each of the first extension 28 and the second extension 30 may include only a flat portion or only a tapered portion. In this specification, “substantially constant thickness” refers to a thickness within a manufacturing variation range (for example, 20%). Each of the first extension 28 and the second extension 30 may have a thickness in a range of 5 nm to 100 nm. The flat portion of each of the first extension 28 and the second extension 30 excluding the tapered portion may have a thickness in a range of 5 nm to 25 nm.

In the example shown in FIG. 1, the first extension 28 may extend longer than the second extension 30 outward from the ridge 26 in plan view. In this case, the flat portion of the first extension 28 is formed in a wider region than the flat portion of the second extension 30.

In another example, the gate layer 22 may include only one of the first extension 28 and the second extension 30 in addition to the ridge 26. In an example, the gate layer 22 may include the ridge 26 and the first extension 28 and exclude the second extension 30. In another example, the gate layer 22 may include the ridge 26 and exclude the first extension 28 and the second extension 30.

The gate electrode 24 is formed on the upper surface 22B of the gate layer 22. The ridge 26 includes the upper surface 22B of the gate layer 22. In other words, the gate electrode 24 is formed on the ridge 26 of the gate layer 22. The gate electrode 24 is composed of one or more metal layers, an example of which is a titanium nitride (TiN) layer. Alternatively, the gate electrode 24 may include a first metal layer composed of Ti and a second metal layer composed of TiN and arranged on the first metal layer. The gate electrode 24 may have a thickness in a range of, for example, 50 nm to 200 nm. The gate electrode 24 may form a Schottky junction with the gate layer 22.

The passivation layer 32 covers the electron supply layer 18, the gate layer 22, and the gate electrode 24 and includes the first opening 32A and the second opening 32B. The first opening 32A and the second opening 32B of the passivation layer 32 are separated from the gate layer 22. The gate layer 22 is arranged between the first opening 32A and the second opening 32B. More specifically, the gate layer 22 may be arranged between the first opening 32A and the second opening 32B at a position closer to the second opening 32B than to the first opening 32A. The passivation layer 32 covers the upper surface of the electron supply layer 18, the side surface and the upper surface 22B of the gate layer 22, and the side surface and the upper surface of the gate electrode 24. Thus, the passivation layer 32 includes a non-flat surface.

The drain electrode 34 and the source electrode 36 may be composed of one or more metal layers (e.g., combination of Ti layer, TiN layer, Al layer, Al SiCu layer, AlCu layer, and the like). At least a portion of the drain electrode 34 fills the first opening 32A. At least a portion of the source electrode 36 fills the second opening 32B. The drain electrode 34 and the source electrode 36 are in ohmic contact with 2DEG present immediately under the electron supply layer 18 through the first opening 32A and the second opening 32B, respectively.

The source electrode 36 includes a source contact 36A filling the second opening 32B and a source field plate 36B covering the passivation layer 32. The source field plate 36B is continuous with the source contact 36A and is formed integrally with the source contact 36A. In plan view, the source field plate 36B includes an end 36C located between the first opening 32A and the gate layer 22. The source field plate 36B extends from the source contact 36A to the end 36C along the surface of the passivation layer 32 toward the drain electrode 34 but is spaced apart from the drain electrode 34. Since the source field plate 36B extends along the non-flat surface of the passivation layer 32, the source field plate 36B includes a non-flat surface in the same manner. When a drain voltage is applied to the drain electrode 34 while no gate voltage is applied to the gate electrode 24, the source field plate 36B reduces concentration of electric field in the vicinity of the end of the gate electrode 24.

The passivation layer 32 will be further described in detail.

The passivation layer 32 may include a first insulation layer 38 and a second insulation layer 40. The first insulation layer 38 is formed on a portion of the electron supply layer 18 located between the first opening 32A and the gate layer 22 in plan view. The second insulation layer 40 is formed on the electron supply layer 18 located between the second opening 32B and the gate layer 22 in plan view and covers the gate layer 22 and the gate electrode 24. A portion of the second insulation layer 40 may be formed on at least a portion of the first insulation layer 38. In the example shown in FIG. 1, the first insulation layer 38 is completely covered by the second insulation layer 40. Thus, the second insulation layer 40 covers the electron supply layer 18, the gate layer 22, the gate electrode 24, and the first insulation layer 38.

In the example shown in FIG. 1, the first opening 32A of the passivation layer 32 is formed in a region of the passivation layer 32 that includes both the first insulation layer 38 and the second insulation layer 40. The second opening 32B of the passivation layer 32 is formed in a region of the passivation layer 32 that includes only the second insulation layer 40.

The second insulation layer 40 is formed of a material having a smaller Young's modulus than a material forming the first insulation layer 38. Young's modulus is also referred to as a modulus of longitudinal elasticity and is a proportional constant indicating a relationship between strain and stress in the same axis direction. In general, the Young's modulus of SiO₂ is smaller than that of SiON. The Young's modulus of SiON is smaller than that of SiN. Hence, for example, the first insulation layer 38 may include SiN, and the second insulation layer 40 may include one of SiON and SiO₂. Alternatively, the first insulation layer 38 may be SiN, and the second insulation layer 40 may be SiON or SiO₂. In another example, the first insulation layer 38 may include SiON, and the second insulation layer 40 may include SiO₂. Alternatively, the first insulation layer 38 may be SiON, and the second insulation layer 40 may be SiO₂. In another example, the first insulation layer 38 and the second insulation layer 40 may each include a film of SiN that is formed under a different film forming condition. The different film forming conditions may be used so that the second insulation layer 40 has a smaller Young's modulus than the first insulation layer 38. Alternatively, the first insulation layer 38 and the second insulation layer 40 may each be a film of SiN that is formed under a different film forming condition.

The first insulation layer 38 may include a first end 38A arranged adjacent to the drain electrode 34 in the first opening 32A and a second end 38B arranged between the first opening 32A and the gate electrode 24 in plan view. The first end 38A of the first insulation layer 38 coincides with the wall surface of the passivation layer 32 defining the first opening 32A and defines at least a portion of the first opening 32A.

The first insulation layer 38 does not completely cover the gate layer 22 and, in the example shown in FIG. 1, covers only a portion of the first extension 28 of the gate layer 22. The second end 38B is arranged on the first extension 28 so that a portion of the first insulation layer 38 is formed on a portion of the first extension 28. The distance between the second end 38B of the first insulation layer 38 and the ridge 26 of the gate layer 22 (i.e., distance between the second end 38B and the first ridge end 26A) may be greater than or equal to 50 nm in plan view.

The first insulation layer 38 may have a thickness in a range of 50 nm to 200 nm. In FIG. 1, for the sake of simplicity, the first insulation layer 38 is shown to have a flat upper surface (so that the thickness is smaller on the first extension 28 than on the electron supply layer 18). However, the thickness of the actual first insulation layer 38 on the first extension 28 is substantially the same as that on the electron supply layer 18.

In plan view, a portion of the first extension 28 located between the second end 38B of the first insulation layer 38 and the ridge 26 of the gate layer 22 (i.e., between the second end 38B and the first ridge end 26A) is directly covered by the second insulation layer 40. Thus, a portion of the second insulation layer 40 is formed on at least a portion of the first extension 28.

In the example shown in FIG. 1, the source field plate 36B is formed on the second insulation layer 40, which covers the first insulation layer 38. The end 36C of the source field plate 36B is arranged on the second insulation layer 40 and is spaced apart from the drain electrode 34.

The second insulation layer 40 may have a thickness in a range of 50 nm to 200 nm. The thickness of the first insulation layer 38 may be smaller than the thickness of the second insulation layer 40, may be larger than the thickness of the second insulation layer 40, or may be substantially the same as the thickness of the second insulation layer 40. In the example shown in FIG. 1, the first insulation layer 38 is completely covered by the second insulation layer 40. Therefore, in a region adjacent to the drain electrode 34 in the first opening 32A, the thickness of the passivation layer 32 is the sum of the thicknesses of the first insulation layer 38 and the second insulation layer 40. In a region adjacent to the source contact 36A, the thickness of the passivation layer 32 corresponds to the thickness of the second insulation layer 40. Hence, in the example shown in FIG. 1, in the region adjacent to the source contact 36A, the electron supply layer 18 is covered by a relatively thin portion of the passivation layer 32 regardless of the thicknesses of the first insulation layer 38 and the second insulation layer 40.

Stress applied to the electron supply layer 18 from the first insulation layer 38 and the second insulation layer 40 will now be described. Also, changes caused by the stress in the sheet carrier of a 2DEG 20 generated in the electron transit layer 16 will be described.

The first insulation layer 38 has a relatively large Young's modulus. Therefore, in the region covered by the first insulation layer 38, a relatively large stress is applied to the electron supply layer 18 from the first insulation layer 38. As the stress applied to the electron supply layer 18 increases, a larger amount of the 2DEG 20 is generated in the electron transit layer 16 at a position close to the heterojunction interface between the electron transit layer 16 and the electron supply layer 18 due to the piezoelectric effect. In this specification, as described above, a region in which the 2DEG 20 having a relatively high sheet carrier density is generated in the electron transit layer 16 is referred to as a high carrier density region. In the example shown in FIG. 1, a high carrier density region 42H is formed in the electron transit layer 16 located under the first insulation layer 38. In addition, when an additional layer is formed on the first insulation layer 38 (for example, in FIG. 1, the second insulation layer 40 is formed), additional stress is applied to the electron supply layer 18 from the additional layer. This may increase the sheet carrier density of the 2DEG 20.

The second insulation layer 40 has a relatively small Young's modulus. Therefore, in a region that is covered by the second insulation layer 40 and is not covered by the first insulation layer 38, a relatively small stress is applied to the electron supply layer 18 from the second insulation layer 40. This shows that, in this region, the 2DEG 20 having a relatively low sheet carrier density is generated in the electron transit layer 16. In this specification, as described above, a region in which the 2DEG 20 having a relatively low sheet carrier density is generated in the electron transit layer 16 is referred to as a low carrier density region. In the example shown in FIG. 1, in the electron transit layer 16, a first low carrier density region 42L1 is formed between the first ridge end 26A and the high carrier density region 42H in plan view, and a second low carrier density region 42L2 is formed between the second ridge end 26B and the second opening 32B in plan view.

Since the ridge 26 of the gate layer 22 is formed of a relatively thick p-type GaN layer, the 2DEG 20 is not generated in the electron transit layer 16 under the ridge 26. More specifically, as long as a voltage applied to the gate electrode 24 does not exceed the threshold voltage, a region with no 2DEG 20 is formed between the first low carrier density region 42L1 and the second low carrier density region 42L2.

In the example shown in FIG. 1, the gate layer 22 includes the first extension 28 and the second extension 30, each of which is located between the electron supply layer 18 and the first insulation layer 38 or the second insulation layer 40. The first extension 28 and the second extension 30 are formed from a p-type GaN layer in the same manner as the ridge 26. Therefore, it is considered that the sheet carrier density of the 2DEG 20 generated in the electron transit layer 16 under the first extension 28 and the second extension 30 is lower than that when the first extension 28 and the second extension 30 are not present. However, because of being smaller in thickness than the ridge 26, the first extension 28 and the second extension 30 have a relatively small effect on the sheet carrier density of the 2DEG 20 generated in the electron transit layer 16 under the first extension 28 and the second extension 30.

In a region where the first extension 28 or the second extension 30 is present, the first insulation layer 38 and the second insulation layer 40 apply stress to the electron supply layer 18 through the first extension 28 or the second extension 30. Even in this case, the first insulation layer 38 applies a relatively large stress to the electron supply layer 18, whereas the second insulation layer 40 applies a relatively small stress to the electron supply layer 18.

When the first insulation layer 38 and the second insulation layer 40, which apply different stresses to the electron supply layer 18, are arranged in accordance with the present embodiment, the first low carrier density region 42L1, the second low carrier density region 42L2, and the high carrier density region 42H, which differ from each other in the sheet carrier density of 2DEG, are formed in the electron transit layer 16. Specifically, the first low carrier density region 42L1 and the second low carrier density region 42L2 are respectively arranged in the vicinity of the first ridge end 26A and the second ridge end 26B, in which an electric field is likely to concentrate. Thus, concentration of electric field is inhibited effectively. As a result, the leakage of current is reduced during application of a high gate voltage. In contrast, the high carrier density region 42H is arranged in a position separated from the first ridge end 26A, where the concentration of electric field is less likely to occur. Thus, an excessive increase in the on-resistance of the nitride semiconductor device 10 is avoided.

In the present embodiment, the maximum rating of gate-source voltage of the nitride semiconductor device 10 is greater than or equal to 8 V during application of a positive bias and is greater than or equal to 4 V during application of a negative bias.

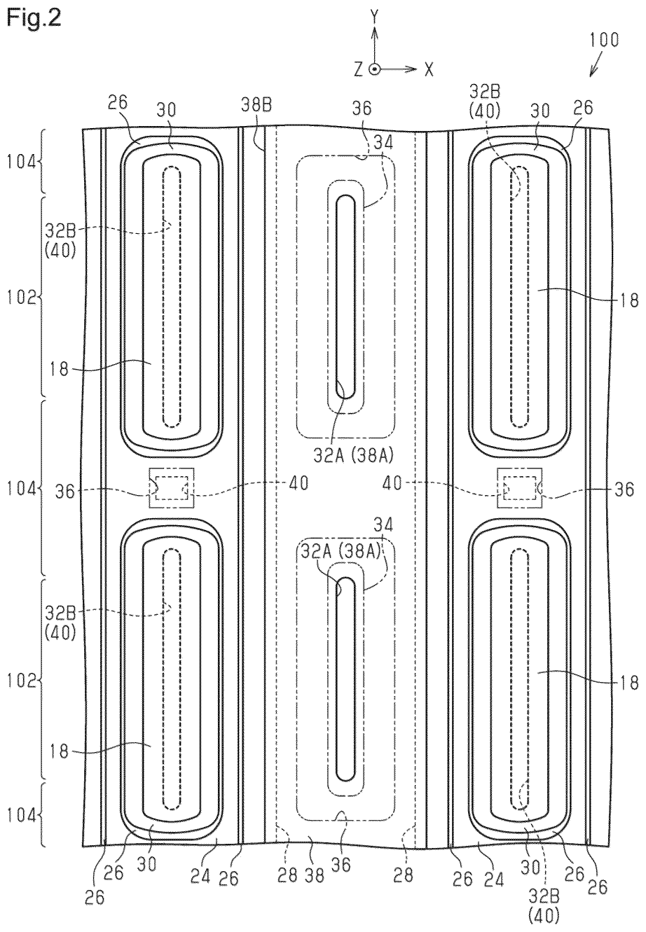

FIG. 2 is a schematic plan view showing an exemplary pattern 100 formed in the nitride semiconductor device 10 shown in FIG. 1. To facilitate understanding, in FIG. 2, the same reference characters are given to those components that are the same as the corresponding components shown in FIG. 1. In addition, the drain electrode 34, the source electrode 36, and the second insulation layer 40 are transparently shown so that components of layers underneath are visible. Outer edges of the drain electrode 34 and the source electrode 36 are indicated by double-dashed lines. Outer edges of the second insulation layer 40 are indicated by broken lines.

As shown in FIG. 2, the pattern 100 includes active regions 102 that contribute to operation of the transistor and inactive regions 104 that do not contribute to operation of the transistor. The active region 102 refers to a region in which, when voltage is applied to the gate electrode 24, current flows between the source and the drain.

In the active region 102, multiple (in FIG. 2, four) nitride semiconductor devices are continuously formed in the X-direction. Each nitride semiconductor device shown in FIG. 2 corresponds to the nitride semiconductor device 10 shown in FIG. 1. More specifically, the cross-sectional view shown in FIG. 1 corresponds to a cross section of the pattern 100 in the active region 102 enlarging a portion that includes one nitride semiconductor device 10 (including gate electrode 24, and drain electrode 34 and source electrode 36 associated with the gate electrode 24).

In plan view, the first insulation layer 38 is formed in a region relatively close to the drain electrode 34 in the first opening 32A and is not formed in a region relatively close to the source electrode 36 (i.e., the source contact 36A) in the second opening 32B. The first insulation layer 38 partially covers the first extension 28. Hence, in FIG. 2, outer edges of the first extension 28 are indicated by broken lines.

An example of a method for manufacturing the nitride semiconductor device 10 shown in FIG. 1 will be described.

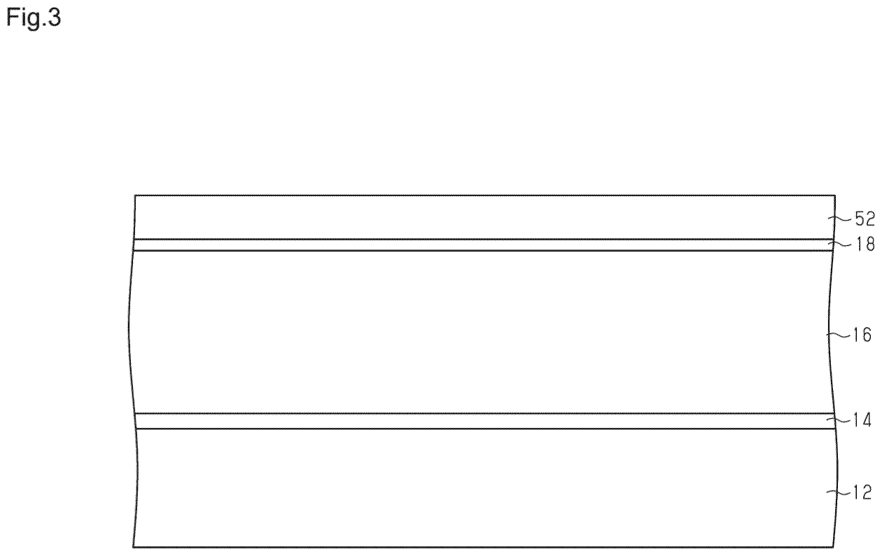

FIGS. 3 to 12 are schematic cross-sectional views showing exemplary manufacturing steps of the nitride semiconductor device 10. To facilitate understanding, in FIGS. 3 to 12, the same reference characters are given to those components that are the same as the corresponding components shown in FIG. 1.

As shown in FIG. 3, the method for manufacturing the nitride semiconductor device 10 includes sequentially forming the buffer layer 14, the electron transit layer 16, the electron supply layer 18, and a nitride semiconductor layer 52 on the substrate 12, which is, for example, a Si substrate.

Metal organic chemical vapor deposition (MOCVD) may be used to epitaxially grow the buffer layer 14, the electron transit layer 16, the electron supply layer 18, and the nitride semiconductor layer 52.

Although not shown in detail, in an example, the buffer layer 14 is multilayer. An AlN layer (the first buffer layer) is formed on the substrate 12, and then a graded AlGaN layer (the second buffer layer) is formed on the AlN layer. The graded AlGaN layer is formed, for example, by stacking three AlGaN layers having Al compositions of 75%, 50%, and 25% in that order from the side of the AlN layer.

A GaN layer is formed on the buffer layer 14 as the electron transit layer 16. An AlGaN layer is formed on the electron transit layer 16 as the electron supply layer 18. Thus, the electron supply layer 18 has a band gap that is larger than that of the electron transit layer 16.

Then, a GaN layer including an acceptor impurity is formed on the electron supply layer 18 as the nitride semiconductor layer 52.

The buffer layer 14, the electron transit layer 16, the electron supply layer 18, and the nitride semiconductor layer 52 are composed of nitride semiconductors having lattice constants relatively close to each other. This allows for sequential epitaxial growth of the layers.

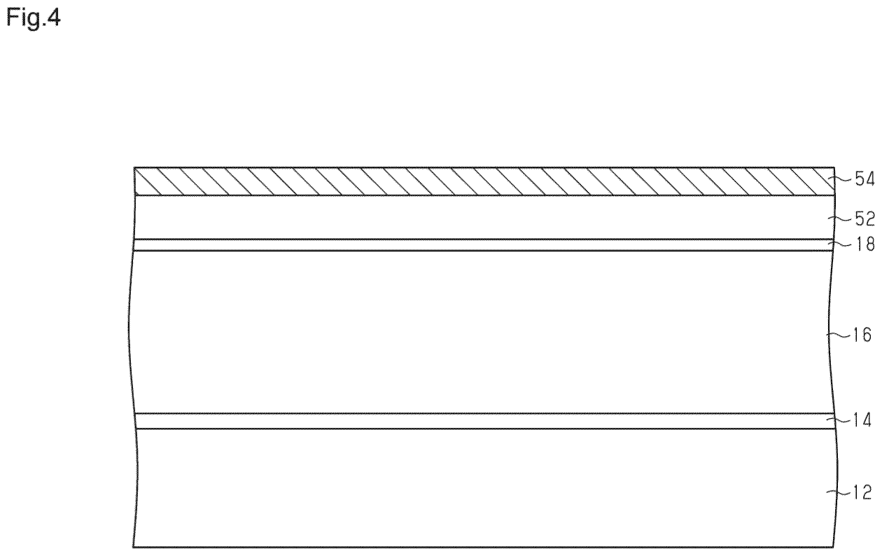

FIG. 4 is a schematic cross-sectional view showing a manufacturing step subsequent to FIG. 3. As shown in FIG. 4, the manufacturing method of the nitride semiconductor device 10 further includes forming a metal layer 54 on the nitride semiconductor layer 52. In an example, the metal layer 54 is a TiN layer formed through sputtering.

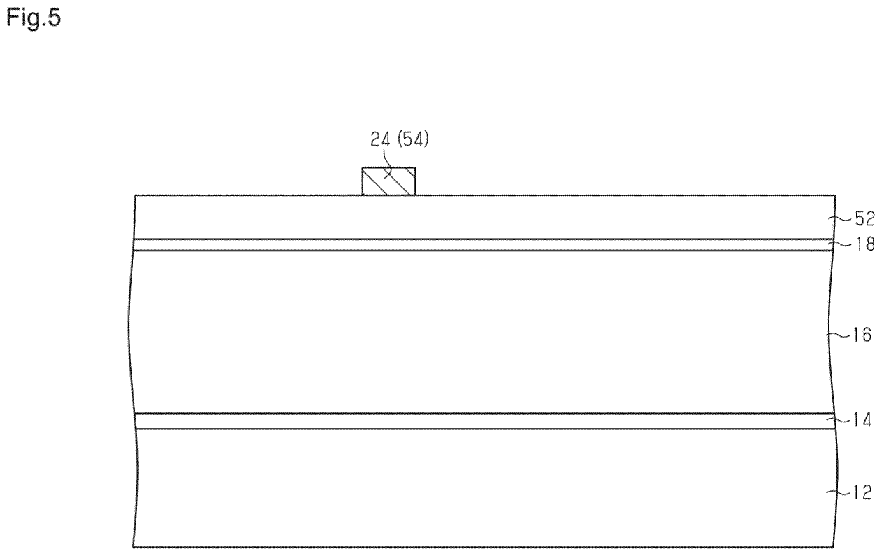

FIG. 5 is a schematic cross-sectional view showing a manufacturing step subsequent to FIG. 4. As shown in FIG. 5, the method for manufacturing the nitride semiconductor device 10 further includes selectively removing the metal layer 54 by lithography and etching to form the gate electrode 24.

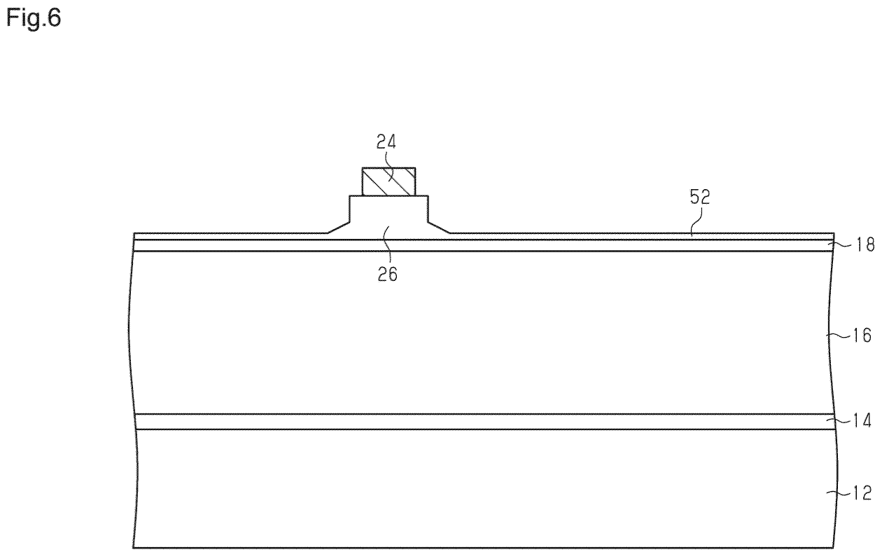

FIG. 6 is a schematic cross-sectional view showing a manufacturing step subsequent to FIG. 5. As shown in FIG. 6, the method for manufacturing the nitride semiconductor device 10 further includes patterning the nitride semiconductor layer 52 by lithography and etching to form the ridge 26.

In an example, the upper surface and the side surfaces of the gate electrode 24 are covered by a mask (not shown), and the mask is used to pattern the nitride semiconductor layer 52 by dry etching. As a result of the etching, the nitride semiconductor layer 52 located under the mask remains to form the ridge 26 of the gate layer 22 shown in FIG. 1. The nitride semiconductor layer 52 that is not covered by the mask is etched to a predetermined depth. In this step, the nitride semiconductor layer 52 may be etched to have a thickness that gradually decreases as the ridge 26 becomes farther in a region adjacent to the ridge 26 and a substantially constant thickness in a region located beyond a predetermined distance from the ridge 26.

The patterning process shown in FIG. 6 may include a number of patterning steps performed to obtain a desired shape as described above or a single etching step performed under a condition selected so that the etching speed is decreased in the vicinity of the structure covered by the mask. Alternatively, a SiN film that can be conformally deposited may be formed on and both sides of the gate electrode 24. By selectively removing the nitride semiconductor layer 52 using the SiN film as a hard mask, the structure shown in FIG. 6 can be obtained.

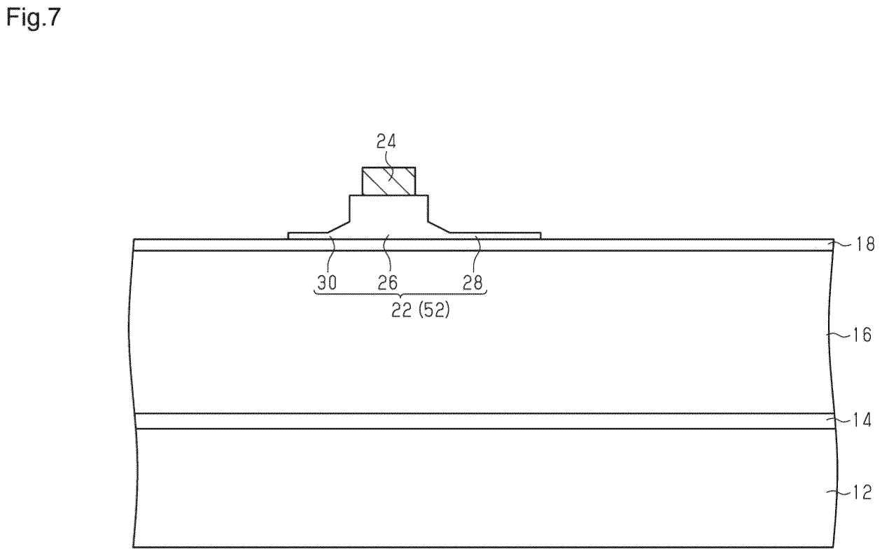

FIG. 7 is a schematic cross-sectional view showing a manufacturing step subsequent to FIG. 6. As shown in FIG. 7, the method for manufacturing the nitride semiconductor device 10 further includes patterning the nitride semiconductor layer 52 by lithography and etching to form the first extension 28 and the second extension 30.

In an example, the gate electrode 24, the ridge 26, and portions of the nitride semiconductor layer 52 corresponding to the first extension 28 and the second extension 30 are covered by a mask (not shown). The mask is used to pattern the nitride semiconductor layer 52 by dry etching.

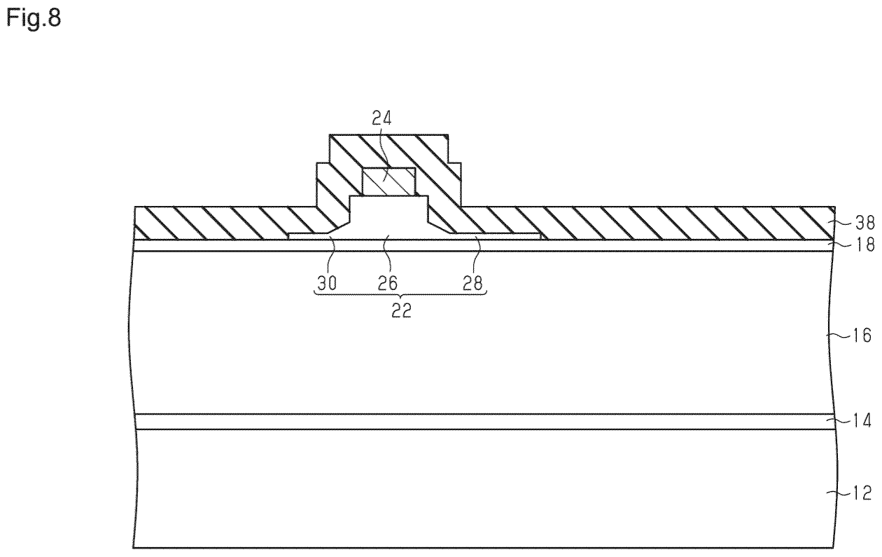

FIG. 8 is a schematic cross-sectional view showing a manufacturing step subsequent to FIG. 7. As shown in FIG. 8, the method for manufacturing the nitride semiconductor device 10 further includes forming the first insulation layer 38 to cover the entirety of exposed surfaces of the electron supply layer 18, the gate layer 22, and the gate electrode 24. In an example, the first insulation layer 38 is a SiN layer formed by low-pressure chemical vapor deposition (LPCVD).

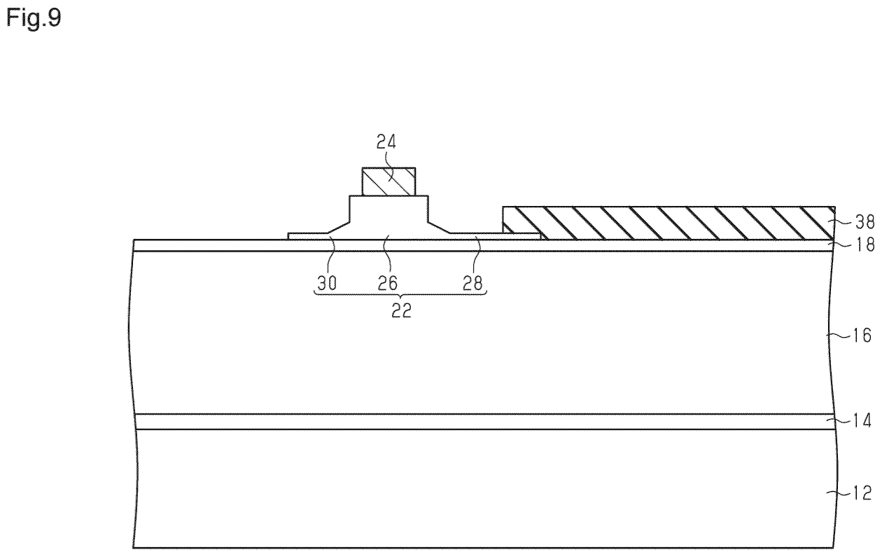

FIG. 9 is a schematic cross-sectional view showing a manufacturing step subsequent to FIG. 8. As shown in FIG. 9, the method for manufacturing the nitride semiconductor device 10 further includes selectively removing the first insulation layer 38 by lithography and etching. The first insulation layer 38 is selectively removed so that a portion of the first extension 28 (portion located toward the ridge 26), the ridge 26, the gate electrode 24, the second extension 30, and the electron supply layer 18 adjacent to the second extension 30 are exposed. As a result, the first insulation layer 38 remains on a portion of the first extension 28 and the electron supply layer 18 in a region adjacent to the first extension 28. The end (the second end 38B) is located on the first extension 28.

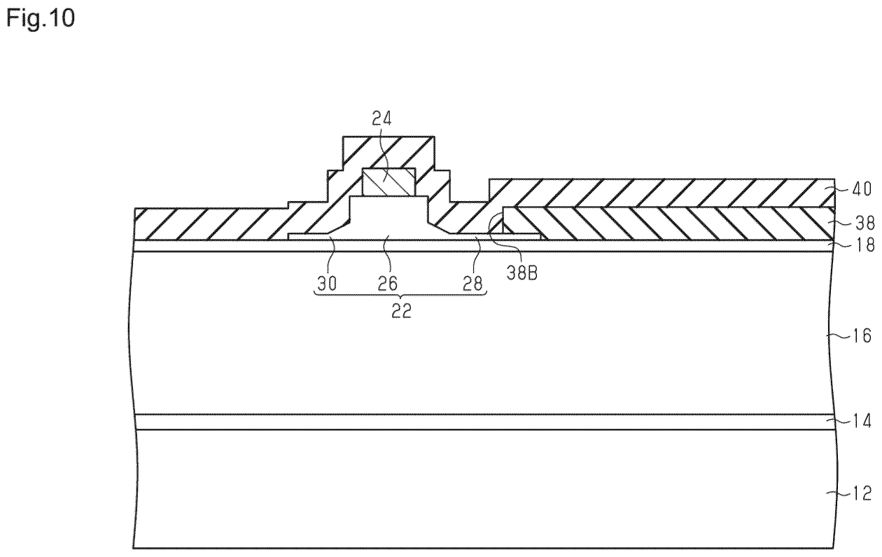

FIG. 10 is a schematic cross-sectional view showing a manufacturing step subsequent to FIG. 9. As shown in FIG. 10, the method for manufacturing the nitride semiconductor device 10 further includes forming the second insulation layer 40 to cover the entirety of exposed surfaces of the electron supply layer 18, the gate layer 22, the gate electrode 24, and the first insulation layer 38. In an example, the second insulation layer 40 is a SiO₂ layer formed by plasma CVD. The first insulation layer 38 and the second insulation layer 40 are together referred to as the passivation layer 32.

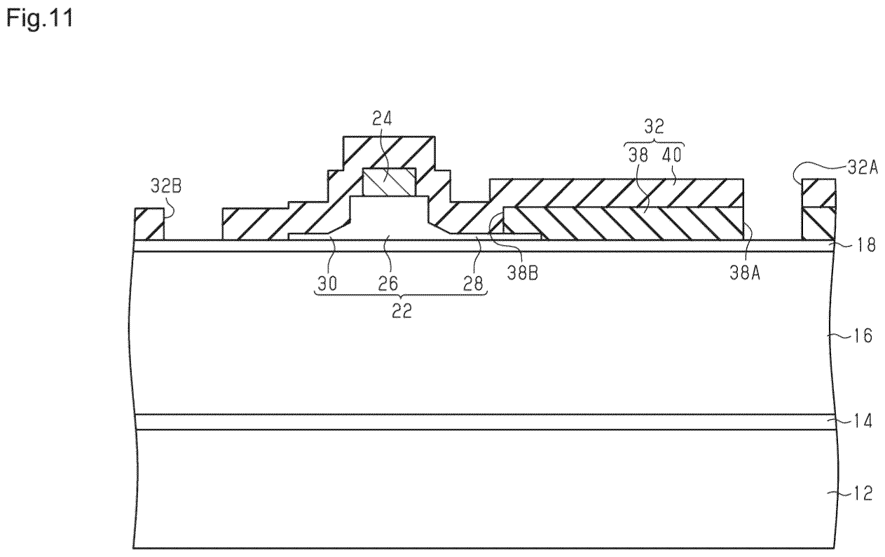

FIG. 11 is a schematic cross-sectional view showing a manufacturing step subsequent to FIG. 10. As shown in FIG. 11, the method for manufacturing the nitride semiconductor device 10 further includes selectively removing the passivation layer 32 by lithography and etching to form the first opening 32A and the second opening 32B. The first opening 32A and the second opening 32B are formed so that the gate layer 22 is arranged between the first opening 32A and the second opening 32B. The gate layer 22 may be located closer to the second opening 32B than the first opening 32A. The first end 38A of the first insulation layer 38, which has been described with reference to FIG. 1, defines at least a portion of the first opening 32A.

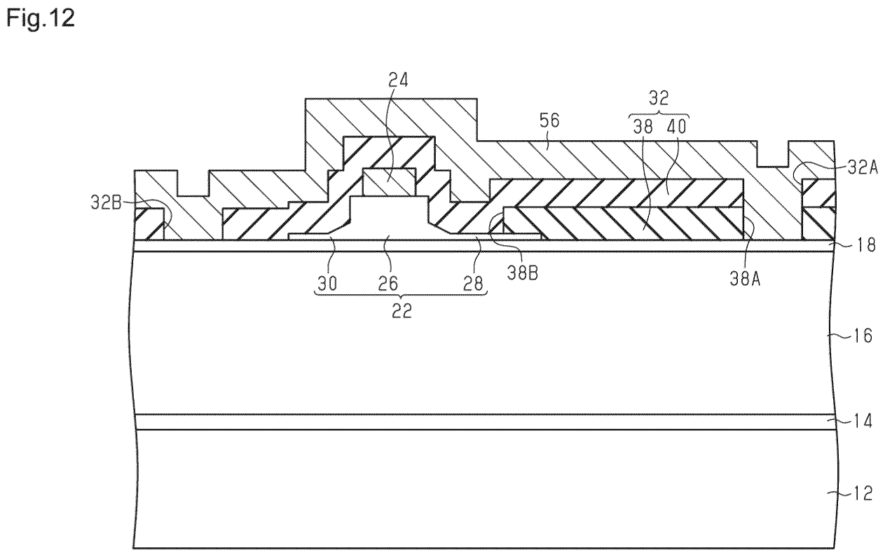

FIG. 12 is a schematic cross-sectional view showing a manufacturing step subsequent to FIG. 11. As shown in FIG. 12, the method for manufacturing the nitride semiconductor device 10 further includes forming a metal layer 56 filling the first opening 32A and the second opening 32B and covering the entirety of exposed surfaces of the passivation layer 32 (the second insulation layer 40). In an example, the metal layer 56 is formed of a combination of metal layers such as a Ti layer, a TiN layer, an Al layer, an Al SiCu layer, and an AlCu layer.

The method for manufacturing the nitride semiconductor device 10 further includes selectively removing the metal layer 56 by lithography and etching to form the drain electrode 34 and the source electrode 36 shown in FIG. 1. Consequently, the nitride semiconductor device 10 shown in FIG. 1 is obtained.

The operation of the nitride semiconductor device 10 of the present embodiment will be described below.

The gate layer 22 of the nitride semiconductor device 10 includes an acceptor impurity and thus raises the energy levels of the electron transit layer 16 and the electron supply layer 18. Thus, when a voltage applied to the gate electrode 24 exceeds the threshold voltage, the 2DEG 20 forms a channel in the electron transit layer 16 and electrically connects the source and the drain. In a zero bias state, the 2DEG 20 is not formed in the region of the electron transit layer 16 located under the ridge 26. Thus, the normally-off operation of the nitride semiconductor device 10 is achieved.

In the electron transit layer 16, the sheet carrier density of the 2DEG 20 in a region where the ridge 26 is not present above becomes higher as stress applied to the electron supply layer 18 increases. This is because piezoelectric polarization generated by strain of the electron supply layer 18 contributes to generation of the 2DEG 20. Therefore, the sheet carrier density of the 2DEG 20 depends on the stress applied from the passivation layer 32 covering the electron supply layer 18, in addition to the thickness and composition of the electron supply layer 18.

In the nitride semiconductor device 10, the passivation layer 32 includes the first insulation layer 38 and the second insulation layer 40. In plan view, the first insulation layer 38 is formed on at least a portion of the electron supply layer 18 located between the first opening 32A and the gate layer 22. In plan view, the second insulation layer 40 is formed on the electron supply layer 18 located between the second opening 32B and the gate layer 22 and covers the gate layer 22 and the gate electrode 24. The second insulation layer 40 is formed of a material having a smaller Young's modulus than a material forming the first insulation layer 38. The second insulation layer 40 having a smaller Young's modulus applies a smaller stress to the electron supply layer 18. The passivation layer 32 includes the second insulation layer 40, formed from a material having a relatively small Young's modulus. This locally reduces the stress applied to the electron supply layer 18, thereby lowering the sheet carrier density of the 2DEG 20.

Specifically, the first low carrier density region 42L1 and the second low carrier density region 42L2, in which the sheet carrier density of the 2DEG 20 is low, are arranged in the vicinity of the first ridge end 26A and the second ridge end 26B, in which an electric field is likely to concentrate. This results in inhibition of the concentration of electric field that can be generated in the vicinity of the ends (the first ridge end 26A and the second ridge end 26B) of the ridge 26 particularly when a negative bias is applied to the gate electrode 24. Such inhibition of the concentration of electric field leads to reduction in leakage of current during application of a high gate voltage and thus improves the maximum rating of gate-source voltage. In contrast, the high carrier density region 42H, in which the sheet carrier density of the 2DEG 20 is high, is arranged in a position separated from the first ridge end 26A, where the concentration of electric field is less likely to occur. Thus, an excessive increase in the on-resistance of the nitride semiconductor device 10 is avoided.

In the present embodiment, the nitride semiconductor HEMT including the p-type GaN layer improves the maximum rating of gate-source voltage during application of a positive bias and a negative bias while maintaining the desirable threshold voltage.

The nitride semiconductor device 10 of the first embodiment has the following advantages.

(1-1) The passivation layer 32 includes the first insulation layer 38 and the second insulation layer 40. In plan view, the first insulation layer 38 is formed on at least a portion of the electron supply layer 18 located between the first opening 32A and the gate layer 22. In plan view, the second insulation layer 40 is formed on the electron supply layer 18 located between the second opening 32B and the gate layer 22 and covers the gate layer 22 and the gate electrode 24. The second insulation layer 40 is formed of a material having a smaller Young's modulus than a material forming the first insulation layer 38.

In this structure, the passivation layer 32, which includes the second insulation layer 40 formed from a material having a relatively low Young's modulus, reduces the stress applied to the electron supply layer 18. This locally lowers the sheet carrier density of the 2DEG 20, thereby inhibiting concentration of electric field.

(1-2) A portion of the second insulation layer 40 may be formed on at least a portion of the first insulation layer 38.

During a process, this structure reduces damages to the electron supply layer 18 located between the gate layer 22 and the first opening 32A in plan view.

(1-3) The first insulation layer 38 includes SiN, and the second insulation layer 40 includes one of SiON and SiO₂.

In this structure, the stress applied from the second insulation layer 40 to the electron supply layer 18 is smaller than the stress applied from the first insulation layer 38 to the electron supply layer 18. This lowers the sheet carrier density of the 2DEG 20 generated under the electron supply layer 18 that is covered by the second insulation layer 40 and is not covered by the first insulation layer 38.

(1-4) The source electrode 36 may include the source contact 36A filling the second opening 32B and the source field plate 36B covering the passivation layer 32. The source field plate 36B may include the end 36C located between the gate electrode 24 and the first opening 32A in plan view.

In this structure, a depletion layer extends from the source field plate 36B toward the 2DEG 20. This limits occurrence of current collapse.

(1-5) The gate layer 22 may include the ridge 26 including the upper surface 22B, on which the gate electrode 24 is formed, and the first extension 28 extending from the ridge 26 toward the first opening 32A in plan view and being smaller in thickness than the ridge 26.

In this structure, the passivation layer 32, which applies a large stress, is not directly formed in the vicinity of the end of the gate layer 22. This avoids an unnecessary increase in the sheet carrier density of the 2DEG 20 at the end of the gate layer 22. In addition, the area of the bottom surface 22A of the gate layer 22 is increased by an amount corresponding to the first extension 28 as compared to a structure in which the gate layer 22 includes only the ridge 26. This reduces the density of holes accumulated in the interface between the gate layer 22 and the electron supply layer 18, thereby reducing the leakage of current.

(1-6) The gate layer 22 may further include the second extension 30 extending from the ridge 26 toward the second opening 32B in plan view and being smaller in thickness than the ridge 26.

In this structure, the passivation layer 32, which applies a large stress, is not directly formed in the vicinity of the end of the gate layer 22. This avoids an unnecessary increase in the sheet carrier density of the 2DEG 20 at the end of the gate layer 22. In addition, the area of the bottom surface 22A of the gate layer 22 is increased by an amount corresponding to the second extension 30 as compared to a structure in which the gate layer 22 includes only the ridge 26 and the first extension 28. This reduces the density of holes accumulated in the interface between the gate layer 22 and the electron supply layer 18, thereby reducing the leakage of current.

(1-7) The ridge 26 may have a thickness greater than 100 nm. Each of the first extension 28 and the second extension 30 may have a thickness in a range of 5 nm to 100 nm. The electron supply layer 18 may have a thickness greater than or equal to 8 nm.

This structure improves the maximum rating of gate-source voltage during application of a positive bias.

(1-8) A portion of the second insulation layer 40 may be formed on at least a portion of the first extension 28.

This structure lowers the sheet carrier density of the 2DEG 20 located under the first extension 28, covered by the second insulation layer 40, thereby inhibiting concentration of electric field.

(1-9) The first insulation layer 38 may include the first end 38A arranged adjacent to the drain electrode 34 in the first opening 32A and the second end 38B arranged between the first opening 32A and the gate electrode 24 in plan view. The second end 38B may be located on the first extension 28.

This structure avoids damages to the electron supply layer 18 that may be caused by the etching of the first insulation layer 38.

(1-10) The second end 38B of the first insulation layer 38 and the ridge 26 of the gate layer 22 may be separated by a distance greater than or equal to 50 nm in plan view.

In this structure, the distance between the second end 38B of the first insulation layer 38 and the ridge 26 of the gate layer 22 is sufficient to increase the effect of lowering the sheet carrier density of the 2DEG 20 located under the first extension 28.

### First Modified Example of First Embodiment

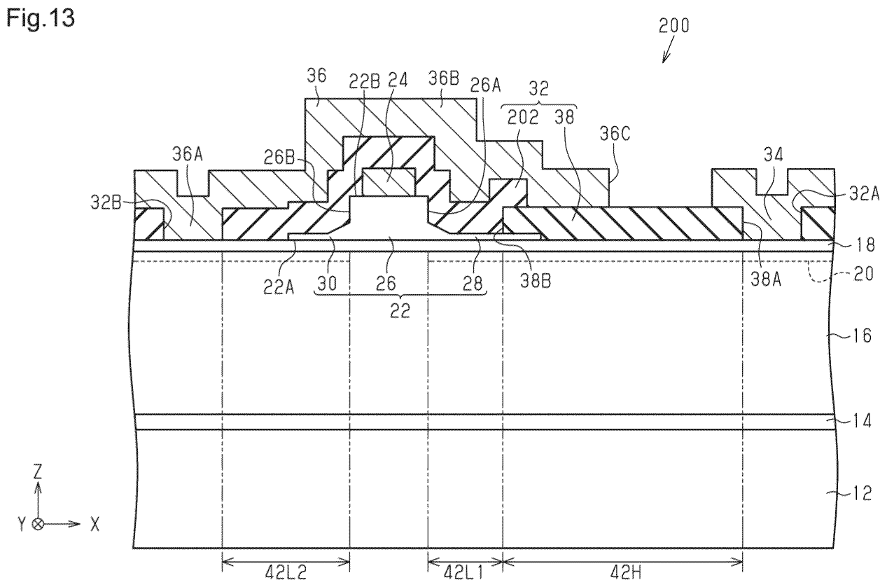

FIG. 13 is a schematic cross-sectional view showing an exemplary nitride semiconductor device 200 in a first modified example of the first embodiment. In FIG. 13, the same reference characters are given to those components that are the same as the corresponding components of the nitride semiconductor device 10 of the first embodiment. Such components will not be described in detail.

The passivation layer 32 of the nitride semiconductor device 200 includes the first insulation layer 38 and a second insulation layer 202. The second insulation layer 202 is formed of a material having a smaller Young's modulus than the material forming the first insulation layer 38. The second insulation layer 202 is formed on the electron supply layer 18 located between the second opening 32B and the gate layer 22 in plan view and covers the gate layer 22 and the gate electrode 24. A portion of the second insulation layer 202 is formed on a portion of the first insulation layer 38. The second insulation layer 202 differs from the second insulation layer 40 shown in FIG. 1 in that the second insulation layer 202 does not cover the entire surface of the first insulation layer 38.

In the example shown in FIG. 13, the first opening 32A of the passivation layer 32 is formed in a region of the passivation layer 32 that includes only the first insulation layer 38. The second opening 32B of the passivation layer 32 is formed in a region of the passivation layer 32 that includes only the second insulation layer 202. The second insulation layer 202 does not cover the entire surface of the first insulation layer 38 and does not extend to the first opening 32A. Therefore, the first opening 32A is defined by the first end 38A of the first insulation layer 38, which differs from that in the example shown in FIG. 1.

The second insulation layer 202 does not cover the entire surface of the first insulation layer 38. A portion of the source field plate 36B directly covers a portion of the first insulation layer 38. Thus, the end 36C of the source field plate 36B is located on the first insulation layer 38.

This structure decreases the thickness of the passivation layer 32 located between the source field plate 36B and the 2DEG 20. Thus, the depletion layer extends more effectively from the source field plate 36B to the 2DEG 20. This limits occurrence of current collapse.

The arrangement of the first insulation layer 38 and the range of the high carrier density region 42H in this modified example are the same as those in the first embodiment. In the modified example, the first insulation layer 38 is not completely covered by the second insulation layer 202. Thus, stress applied to the electron supply layer 18 located under the first insulation layer 38 may be smaller than that of the first embodiment. However, since the second insulation layer 202 is formed of a material having a smaller Young's modulus than the material forming the first insulation layer 38, the sheet carrier density of the 2DEG 20 in the electron transit layer 16 is still high in the high carrier density region 42H as compared to the first low carrier density region 42L1 and the second low carrier density region 42L2.

### Second Modified Example of First Embodiment

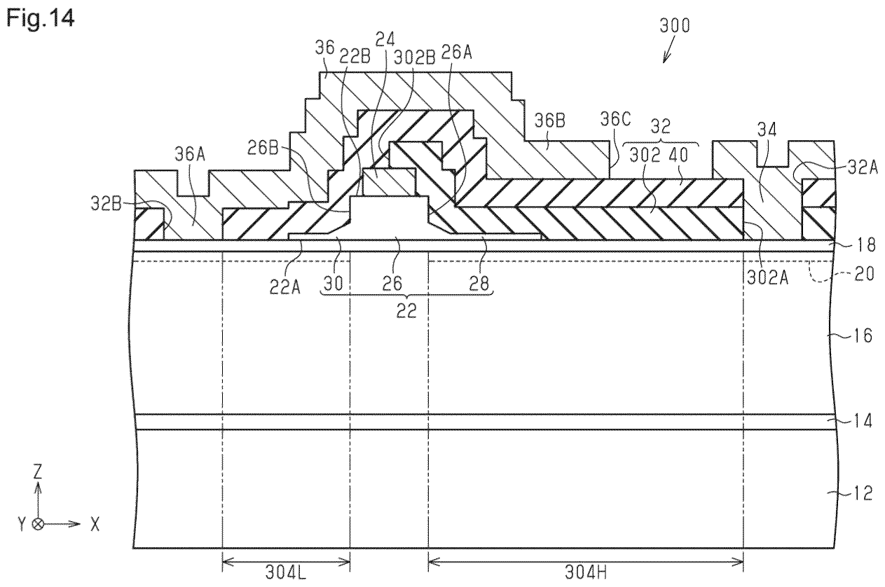

FIG. 14 is a schematic cross-sectional view showing an exemplary nitride semiconductor device 300 in a second modified example of the first embodiment. In FIG. 14, the same reference characters are given to those components that are the same as the corresponding components of the nitride semiconductor device 10 of the first embodiment. Such components will not be described in detail.

The passivation layer 32 of the nitride semiconductor device 300 includes a first insulation layer 302 and the second insulation layer 40. The second insulation layer 40 is formed of a material having a smaller Young's modulus than the material forming the first insulation layer 302. The first insulation layer 302 is formed on a portion of the electron supply layer 18 located between the first opening 32A and the gate layer 22 in plan view.

In the example shown in FIG. 14, the first opening 32A of the passivation layer 32 is formed in a region of the passivation layer 32 that includes both the first insulation layer 302 and the second insulation layer 40. The second opening 32B of the passivation layer 32 is formed in a region of the passivation layer 32 that includes only the second insulation layer 40.

The first insulation layer 302 may include a first end 302A arranged adjacent to the drain electrode 34 in the first opening 32A and a second end 302B arranged on the gate electrode 24. Thus, the first insulation layer 302 covers at least a portion of the gate electrode 24, which differs from that in the example shown in FIG. 1. Even in this case, concentration of electric field in the vicinity of the second ridge end 26B is inhibited since the second extension 30 and the electron supply layer 18 located between the second opening 32B and the gate layer 22 in plan view are covered by the second insulation layer 40, formed of a material having a relatively small Young's modulus.

In the example shown in FIG. 14, the first extension 28 and the electron supply layer 18 located between the first opening 32A and the gate layer 22 in plan view are covered by the first insulation layer 302. This shows that the range of the electron supply layer 18 covered by the first insulation layer 302, having a relatively large Young's modulus, is increased as compared to the example shown in FIG. 1. Accordingly, a high carrier density region 304H in which the sheet carrier density of the 2DEG 20 generated in the electron transit layer 16 is relatively high is wider than that in the first embodiment. As a result, the on-resistance of the nitride semiconductor device 300 is decreased.

In this modified example including the high carrier density region 304H, which is relatively wide, a low carrier density region 304L corresponding to the second low carrier density region 42L2 shown in FIG. 1 is present, but a region corresponding to the first low carrier density region 42L1 shown in FIG. 1 is not present. In the modified example, when the passivation layer 32 is sufficiently resistant to concentration of electric field in the vicinity of the first ridge end 26A, the low on-resistance and inhibition of concentration of electric field in the vicinity of the second ridge end 26B are both achieved.

### Third Modified Example of First Embodiment

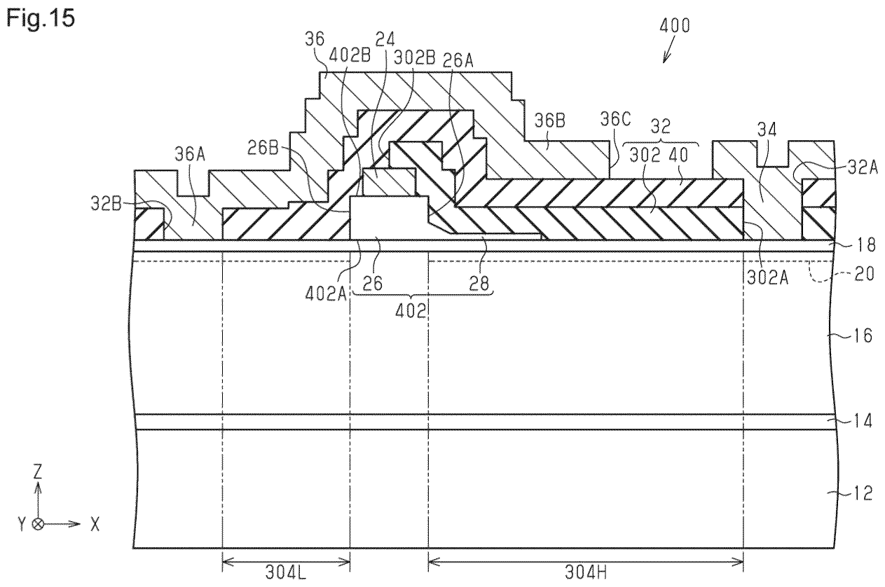

FIG. 15 is a schematic cross-sectional view showing an exemplary nitride semiconductor device 400 in a third modified example of the first embodiment. In FIG. 15, the same reference characters are given to those components that are the same as the corresponding components of the nitride semiconductor device 300 of the second modified example. Such components will not be described in detail.

The nitride semiconductor device 400 includes a gate layer 402. The gate layer 402 includes a bottom surface 402A in contact with the electron supply layer 18 and an upper surface 402B opposite to the bottom surface 402A. The gate layer 402 may include the ridge 26 including the upper surface 402B, on which the gate electrode 24 is formed, and the first extension 28 extending from the ridge 26 toward the first opening 32A in plan view and being smaller in thickness than the ridge 26. The gate layer 402 does not include the second extension 30, which differs from the gate layer 22 shown in the example shown in FIG. 14. This structure simplifies adjustment of the distance between the source contact 36A and the gate layer 402 to a desired value and improves throughput yield in addition to obtaining the same advantages as the second modified example.

### Second Embodiment

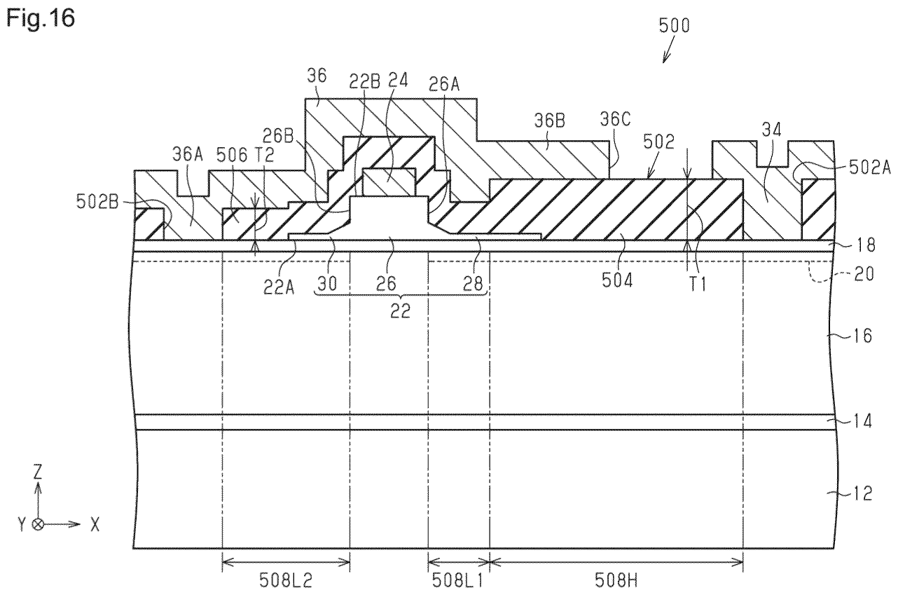

FIG. 16 is a schematic cross-sectional view showing an exemplary nitride semiconductor device 500 of a second embodiment. In FIG. 16, the same reference characters are given to those components that are the same as the corresponding components of the nitride semiconductor device 10 of the first embodiment. Such components will not be described in detail.

In the second embodiment, the nitride semiconductor device 500 includes a passivation layer 502 covering the electron supply layer 18, the gate layer 22, and the gate electrode 24 and including a first opening 502A and a second opening 502B. The passivation layer 502 differs from the passivation layer 32 shown in FIG. 1 in that the passivation layer 502 is formed of a single insulation layer.

The passivation layer 502 covers the upper surface of the electron supply layer 18, the side surface and the upper surface 22B of the gate layer 22, and the side surface and the upper surface of the gate electrode 24. Thus, the passivation layer 502 includes a non-flat surface. However, in regions adjacent to the first opening 502A and the second opening 502B, the passivation layer 502 directly formed on the electron supply layer 18 includes a substantially flat surface because the gate layer 22 and the gate electrode 24 are not present.

The passivation layer 502 includes a first part 504 formed on at least a portion of the electron supply layer 18 located between the first opening 502A and the gate layer 22 in plan view and a second part 506 formed on the electron supply layer 18 located between the second opening 502B and the gate layer 22 in plan view. The second part 506 is smaller in thickness than the first part 504.

The first part 504 of the passivation layer 502 is arranged adjacent to the drain electrode 34 in the first opening 502A and corresponds to a flat part of the passivation layer 502 having a substantially constant thickness Ti. The second part 506 of the passivation layer 502 is arranged adjacent to the source electrode 36 (i.e., the source contact 36A) in the second opening 502B and corresponds to a flat part of the passivation layer 502 having a substantially constant thickness T2 that is smaller than Ti. Thus, in the example shown in FIG. 16, the electron supply layer 18 in a region adjacent to the drain electrode 34 is covered by the first part 504, which is the relatively thick part of the passivation layer 502. The electron supply layer 18 in a region adjacent to the source contact 36A is covered by the second part 506, which is the relatively thin part of the passivation layer 502.

The thickness T1 of the first part 504 may be in a range of 100 nm to 400 nm, the thickness T2 of the second part 506 may be in a range of 50 nm to 200 nm, and T1>T2.

The part of the first extension 28 of the gate layer 22 located toward the drain electrode 34 is covered by a relatively thick part of the passivation layer 502 having substantially the same thickness as the first part 504. The remaining part (part located toward the first ridge end 26A) of the first extension 28 of the gate layer 22 is covered by a relatively thin part of the passivation layer 502 having substantially the same thickness as the second part 506. Therefore, the thickness of the passivation layer 502 abruptly changes between the thickness T1 and the thickness T2 on a position of the first extension 28. The relatively thin part of the passivation layer 502 having substantially the same thickness as the second part 506 also covers the gate electrode 24, the ridge 26, and the second extension 30, and is continuous with the second part 506.

Stress applied to the electron supply layer 18 from the passivation layer 502 will now be described. Also, changes caused by the stress in the sheet carrier of the 2DEG 20 generated in the electron transit layer 16 will be described.

In a region covered by the relatively thick part of the passivation layer 502 including the first part 504, a relatively large stress is applied to the electron supply layer 18 from the passivation layer 502. As a result, in the example shown in FIG. 16, a high carrier density region 508H is formed in the electron transit layer 16 located under the relatively thick part of the passivation layer 502.

In a region covered by the relatively thin part of the passivation layer 502 including the second part 506, a relatively small stress is applied to the electron supply layer 18 from the passivation layer 502. As a result, in the example shown in FIG. 16, in the electron transit layer 16, a first low carrier density region 508L1 is formed between the first ridge end 26A and the high carrier density region 508H in plan view, and a second low carrier density region 508L2 is formed between the second ridge end 26B and the second opening 502B in plan view.

Since the ridge 26 of the gate layer 22 is formed of a relatively thick p-type GaN layer, the 2DEG 20 is not generated in the electron transit layer 16 under the ridge 26. More specifically, as long as a voltage applied to the gate electrode 24 does not exceed the threshold voltage, a region with no 2DEG 20 is formed between the first low carrier density region 508L1 and the second low carrier density region 508L2.

In the example shown in FIG. 16, the gate layer 22 includes the first extension 28 and the second extension 30, each of which is located between the electron supply layer 18 and the passivation layer 502. The first extension 28 and the second extension 30 are formed from a p-type GaN layer in the same manner as the ridge 26. Therefore, it is considered that the sheet carrier density of the 2DEG 20 generated under the first extension 28 and the second extension 30 in the electron transit layer 16 is lower than that when the first extension 28 and the second extension 30 are not present. However, because of being smaller in thickness than the ridge 26, the first extension 28 and the second extension 30 have a relatively small effect on the sheet carrier density of the 2DEG 20 generated in the electron transit layer 16 under the first extension 28 and the second extension 30.

In a region where the first extension 28 or the second extension 30 is present, the passivation layer 502 applies stress to the electron supply layer 18 through the first extension 28 or the second extension 30. Even in this case, the relatively thick part of the passivation layer 502 applies a relatively large stress to the electron supply layer 18, whereas the relatively thin part of the passivation layer 502 applies a relatively small stress to the electron supply layer 18.

In accordance with the present embodiment, when the thickness of the passivation layer 502 is changed in accordance with the position, the first low carrier density region 508L1, the second low carrier density region 508L2, and the high carrier density region 508H, which differ from each other in the sheet carrier density of 2DEG, are formed in the electron transit layer 16. Specifically, the first low carrier density region 508L1 and the second low carrier density region 508L2 are respectively arranged in the vicinity of the first ridge end 26A and the second ridge end 26B, in which an electric field is likely to concentrate. Thus, concentration of electric field is inhibited effectively. As a result, the leakage of current is reduced during application of a high gate voltage. In contrast, the high carrier density region 508H is arranged in a position separated from the first ridge end 26A, where the concentration of electric field is less likely to occur. Thus, an excessive increase in the on-resistance of the nitride semiconductor device 500 is avoided.

In the present embodiment, the maximum rating of gate-source voltage of the nitride semiconductor device 500 is greater than or equal to 8 V during application of a positive bias and is greater than or equal to 4 V during application of a negative bias.

An example of a method for manufacturing the nitride semiconductor device 500 shown in FIG. 16 will be described.

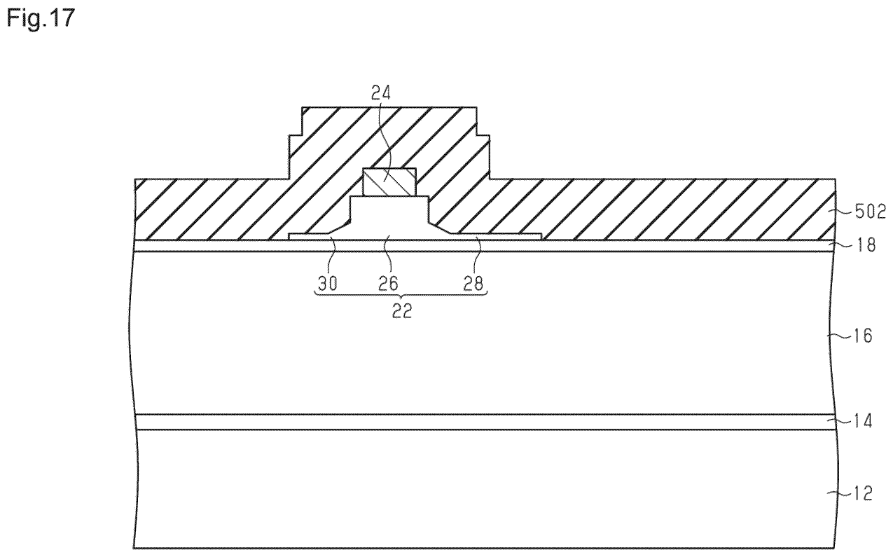

FIGS. 17 to 19 are schematic cross-sectional views showing exemplary manufacturing steps of the nitride semiconductor device 500. To facilitate understanding, in FIGS. 17 to 19, the same reference characters are given to those components that are the same as the corresponding components shown in FIG. 16.

The method for manufacturing the nitride semiconductor device 500 includes the same steps as the steps of manufacturing the nitride semiconductor device 10 shown in FIGS. 3 to 7 and manufacturing steps shown in FIGS. 17 to 19 performed following FIG. 7.

FIG. 17 is a schematic cross-sectional view showing a manufacturing step subsequent to FIG. 7. As shown in FIG. 17, the method for manufacturing the nitride semiconductor device 500 further includes forming the passivation layer 502 to cover the entirety of exposed surfaces of the electron supply layer 18, the gate layer 22, and the gate electrode 24. In an example, the passivation layer 502 is a SiN layer formed by low-pressure chemical vapor deposition (LPCVD). In another example, the passivation layer 502 may be a SiO₂ layer formed by plasma CVD.

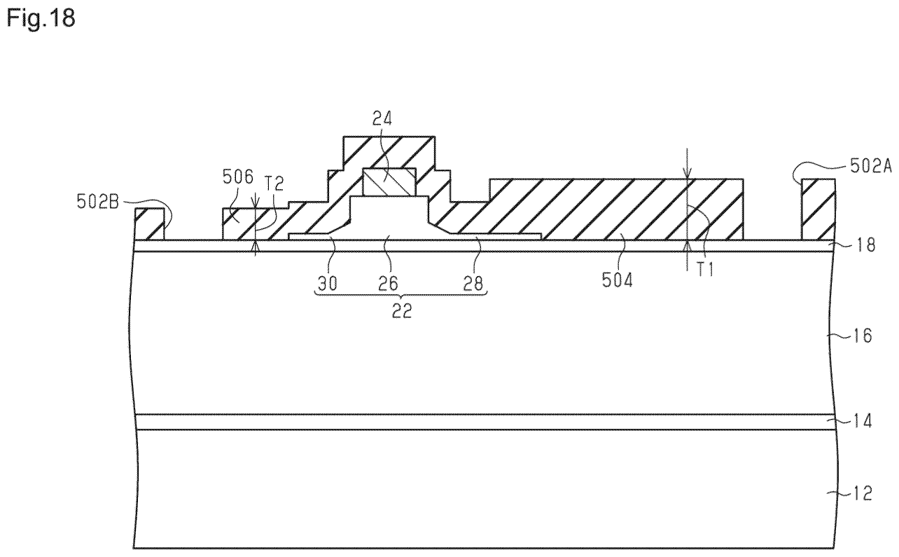

FIG. 18 is a schematic cross-sectional view showing a manufacturing step subsequent to FIG. 17. As shown in FIG. 18, the method for manufacturing the nitride semiconductor device 500 further includes patterning the passivation layer 502 by lithography and etching to include the first part 504 having the thickness T1 and the second part 506 having the thickness T2 and selectively removing the passivation layer 502 to form the first opening 502A and the second opening 502B.

In an example, a mask is formed on the part of the passivation layer 502 corresponding to the first part 504. The mask is used to partially etch the passivation layer 502 to form the second part 506 having the thickness T2, which is smaller than Ti.

Next, the passivation layer 502 is selectively removed to form the first opening 502A and the second opening 502B so that the gate layer 22 is located between the first opening 502A and the second opening 502B. The gate layer 22 may be located closer to the second opening 502B than to the first opening 502A.

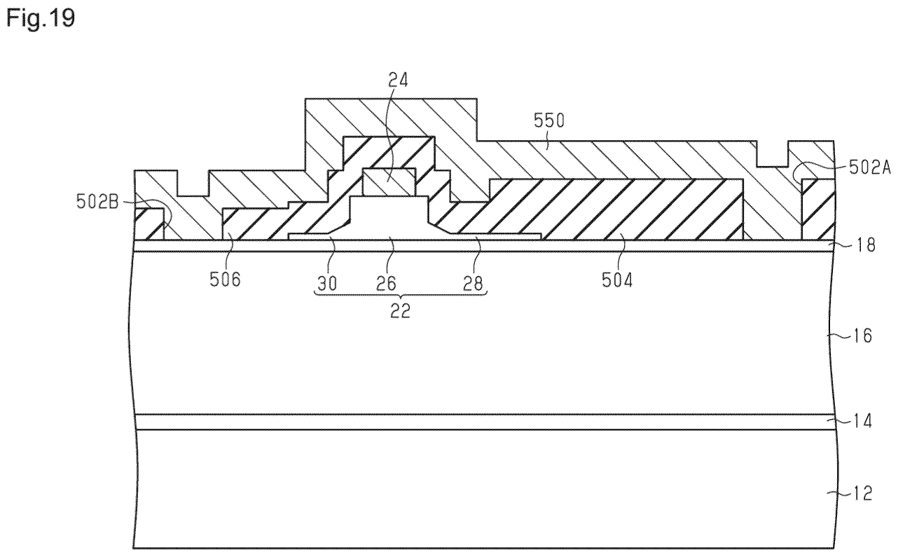

FIG. 19 is a schematic cross-sectional view showing a manufacturing step subsequent to FIG. 18. As shown in FIG. 19, the method for manufacturing the nitride semiconductor device 500 further includes forming a metal layer 550 filling the first opening 502A and the second opening 502B and covering the entirety of exposed surfaces of the passivation layer 502. In an example, the metal layer 550 includes at least one of a Ti layer, a TiN layer, an Al layer, a Cu layer, and an AlCu layer.

The method for manufacturing the nitride semiconductor device 500 further includes selectively removing the metal layer 550 by lithography and etching to form the drain electrode 34 and the source electrode 36 shown in FIG. 16. Consequently, the nitride semiconductor device 500 shown in FIG. 16 is obtained.

The operation of the nitride semiconductor device 500 of the present embodiment will be described below.

In the nitride semiconductor device 500, the passivation layer 502 includes the first part 504 formed on at least a portion of the electron supply layer 18 located between the first opening 502A and the gate layer 22 in plan view and the second part 506 formed on the electron supply layer 18 located between the second opening 502B and the gate layer 22 in plan view. The second part 506 is smaller in thickness than the first part 504. The passivation layer 502 having a smaller thickness applies a smaller stress to the electron supply layer 18. The passivation layer 502 includes the second part 506 having a relatively small thickness. This locally reduces the stress applied to the electron supply layer 18, thereby lowering the sheet carrier density of the 2DEG 20.

Specifically, the first low carrier density region 508L1 and the second low carrier density region 508L2, in which the sheet carrier density of the 2DEG 20 is low, are arranged in the vicinity of the first ridge end 26A and the second ridge end 26B, in which an electric field is likely to concentrate. This results in inhibition of the concentration of electric field that can be generated in the vicinity of the ends (the first ridge end 26A and the second ridge end 26B) of the ridge 26 particularly when a negative bias is applied to the gate electrode 24. Such inhibition of the concentration of electric field leads to reduction in leakage of current during application of a high gate voltage and thus improves the maximum rating of gate-source voltage. In contrast, the high carrier density region 508H, in which the sheet carrier density of the 2DEG 20 is high, is arranged in a position separated from the first ridge end 26A, where the concentration of electric field is less likely to occur. Thus, an excessive increase in the on-resistance of the nitride semiconductor device 500 is avoided.

In the present embodiment, the nitride semiconductor HEMT including the p-type GaN layer improves the maximum rating of gate-source voltage during application of a positive bias and a negative bias while maintaining the desirable threshold voltage.

The nitride semiconductor device 500 of the second embodiment has the following advantages.

(2-1) The passivation layer 502 includes the first part 504 formed on at least a portion of the electron supply layer 18 located between the first opening 502A and the gate layer 22 in plan view and the second part 506 formed on the electron supply layer 18 located between the second opening 502B and the gate layer 22 in plan view. The second part 506 is smaller in thickness than the first part 504.

In this structure, since the passivation layer 502 includes the second part 506 having a relatively small thickness, the stress applied to the electron supply layer 18 is reduced. This locally lowers the sheet carrier density of the 2DEG 20, thereby inhibiting concentration of electric field.

### Other Modified Examples

Each of the embodiments and the modified examples described above may be modified as follows.

The first insulation layer 38 and the second insulation layer 40 may differ from each other in at least one of thickness and material property.

Concentration of electric field in the vicinity of the first ridge end 26A is inhibited as the sheet carrier density of the 2DEG 20 becomes lower in the electron transit layer 16 located between the first opening 32A and the gate layer 22 in plan view. Also, concentration of electric field in the vicinity of the second ridge end 26B is inhibited as the sheet carrier density of the 2DEG 20 becomes lower in the electron transit layer 16 located between the second opening 32B and the gate layer 22 in plan view.

In this regard, in this structure, the first insulation layer 38 and the second insulation layer 40 differ from each other in at least one of thickness and material property. Thus, the sheet carrier density of the 2DEG 20 in the electron transit layer 16 differs between the vicinity of the first opening 32A and the vicinity of the second opening 32B. In an example, the sheet carrier density of the 2DEG 20 may be decreased in a region closer to one of the first ridge end 26A and the second ridge end 26B, in the vicinity of which leakage of current is more likely to occur, to inhibit the concentration of electric field.

In the first embodiment, additionally or alternatively, the second insulation layer 40 may have a smaller thickness than the first insulation layer 38.

In the first embodiment, additionally or alternatively, the second insulation layer 40 may have a smaller thermal expansion coefficient than the first insulation layer 38.

In the second embodiment, the first part 504 and the second part 506 of the passivation layer 502 may be composed of different insulation layers. In an example, the first part 504 may be formed of a SiN layer, and the second part 506 may be formed of a SiO₂ layer. Alternatively, the first part 504 may be formed of a SiO₂ layer and a SiN layer, and the second part 506 may be formed of a SiO₂ layer.

In the drawings, the gate electrode 24 is formed on a portion of the upper surface 22B of the gate layer 22. Instead, the gate electrode 24 may be formed to cover the entirety of the upper surface 22B of the gate layer 22.

One or more of the various examples described in this specification may be combined within a range where there is no technical inconsistency.

In this specification, “at least one of A and B” should be understood to mean “only A, or only B, or both A and B.”

In the present disclosure, the term “on” includes the meaning of “above” in addition to the meaning of “on” unless otherwise clearly indicated in the context. Therefore, the phrase “first layer formed on second layer” is intended to mean that the first layer may be formed on the second layer in contact with the second layer in one embodiment and that the first layer may be located above the second layer without contacting the second layer in another embodiment. In other words, the term “on” does not exclude a structure in which another layer is formed between the first layer and the second layer. For example, a structure in which the electron supply layer 18 is formed on the electron transit layer 16 includes a structure in which an intermediate layer is disposed between the electron supply layer 18 and the electron transit layer 16 to stably form the 2DEG 20.

The directional terms used in the present disclosure such as “vertical,” “horizontal,” “above,” “below,” “top,” “bottom,” “frontward,” “backward,” “longitudinal,” “lateral,” “left,” “right,” “front,” and “back” will depend upon a particular orientation of the device being described and illustrated. The present disclosure may include various alternative orientations. Therefore, the directional terms should not be narrowly construed.

In an example, the Z-direction as referred to in the present disclosure does not necessarily have to be the vertical direction and does not necessarily have to fully conform to the vertical direction. In the structures according to the present disclosure (e.g., the structure shown in FIG. 1), “upward” and “downward” in the Z-direction as referred to in the present description are not limited to “upward” and “downward” in the vertical direction. For example, the X-direction may conform to the vertical direction. The Y-axis direction may conform to the vertical direction.

Clauses

The technical aspects that are understood from the present disclosure will hereafter be described. It should be noted that, for the purpose of facilitating understanding with no intention to limit, elements described in clauses are given the reference characters of the corresponding elements of the embodiments. The reference characters used as examples to facilitate understanding, and the elements in each clause are not limited to those elements given with the reference characters.

[Clause 1]

A nitride semiconductor device, including:
an electron transit layer (16) composed of a nitride semiconductor;
an electron supply layer (18) formed on the electron transit layer (16) and composed of a nitride semiconductor having a band gap that is larger than that of the electron transit layer (16);
a gate layer (22) formed on a portion of the electron supply layer (18) and composed of a nitride semiconductor including an acceptor impurity;
a gate electrode (24) formed on the gate layer (22);
a passivation layer (32) covering the electron supply layer (18), the gate layer (22), and the gate electrode (24) and including a first opening (32A) and a second opening (32B);
a drain electrode (34) in contact with the electron supply layer (18) through the first opening (32A); and
a source electrode (36) in contact with the electron supply layer (18) through the second opening (32B), in which
the gate layer (22) is arranged between the first opening (32A) and the second opening (32B),
the passivation layer (32) includes
   a first insulation layer (38) formed on at least a portion of the electron supply layer (18) located between the first opening (32A) and the gate layer (22) in plan view, and
   a second insulation layer (40) formed on the electron supply layer (18) located between the second opening (32B) and the gate layer (22) in plan view and covering the gate layer (22) and the gate electrode (24), and
the second insulation layer (40) is formed of a material having a smaller Young's modulus than a material forming the first insulation layer (38).

[Clause 2]

A nitride semiconductor device, including:
an electron transit layer (16) composed of a nitride semiconductor;
an electron supply layer (18) formed on the electron transit layer (16) and composed of a nitride semiconductor having a band gap that is larger than that of the electron transit layer (16);
a gate layer (22) formed on a portion of the electron supply layer (18) and composed of a nitride semiconductor including an acceptor impurity;
a gate electrode (24) formed on the gate layer (22);
a passivation layer (32) covering the electron supply layer (18), the gate layer (22), and the gate electrode (24) and including a first opening (32A) and a second opening (32B);
a drain electrode (34) in contact with the electron supply layer (18) through the first opening (32A); and
a source electrode (36) in contact with the electron supply layer (18) through the second opening (32B), in which
the gate layer (22) is arranged between the first opening (32A) and the second opening (32B),
the passivation layer (32) includes
   a first insulation layer (38) formed on at least a portion of the electron supply layer (18) located between the first opening (32A) and the gate layer (22) in plan view, and
   a second insulation layer (40) formed on the electron supply layer (18) located between the second opening (32B) and the gate layer (22) in plan view and covering the gate layer (22) and the gate electrode (24), and
the first insulation layer (38) and the second insulation layer (40) differ from each other in at least one of thickness and material property.

[Clause 3]

The nitride semiconductor device according to clause 1, in which a portion of the second insulation layer (40) is formed on at least a portion of the first insulation layer (38).

[Clause 4]

The nitride semiconductor device according to any one of clauses 1 to 3, in which the second insulation layer (40) is smaller in thickness than the first insulation layer (38).

[Clause 5]

The nitride semiconductor device according to any one of clauses 1 to 4, in which the first insulation layer (38) is SiN, and the second insulation layer (40) is SiON or SiO₂.

[Clause 6]

The nitride semiconductor device according to any one of clauses 1 to 4, in which the first insulation layer (38) includes SiN, and the second insulation layer (40) includes one of SiON and SiO₂.

[Clause 7]

The nitride semiconductor device according to any one of clauses 1 to 4, in which the first insulation layer (38) and the second insulation layer (40) are each a film of SiN that is formed under a different film forming condition, and the second insulation layer (40) has a smaller Young's modulus than the first insulation layer (38) due to the different film forming conditions.

[Clause 8]

The nitride semiconductor device according to any one of clauses 1 to 7, in which the source electrode (36) includes a source contact (36A) filling the second opening (32B) and a source field plate (36B) covering the passivation layer (32), and the source field plate (36B) includes an end (36C) located between the gate electrode (24) and the first opening (32A) in plan view.

[Clause 9]

The nitride semiconductor device according to any one of clauses 1 to 8, in which the gate layer (22) includes
a ridge (26) including an upper surface (22B) on which the gate electrode (24) is formed, and
a first extension (28) extending from the ridge (26) toward the first opening (32A) in plan view and being smaller in thickness than the ridge (26).

[Clause 10]

The nitride semiconductor device according to clause 9, in which the gate layer (22) further includes a second extension (30) extending from the ridge (26) toward the second opening (32B) in plan view and being smaller in thickness than the ridge (26).

[Clause 11]

The nitride semiconductor device according to clause 10, in which the ridge (26) has a thickness greater than 100 nm, each of the first extension (28) and the second extension (30) has a thickness in a range of 5 nm to 100 nm, and the electron supply layer (18) has a thickness greater than or equal to 8 nm.

[Clause 12]

The nitride semiconductor device according to any one of clauses 9 to 11, in which a portion of the second insulation layer (40) is formed on at least a portion of the first extension (28).

[Clause 13]

The nitride semiconductor device according to any one of clauses 9 to 12, in which the first insulation layer (38) includes a first end (38A) arranged adjacent to the drain electrode (34) in the first opening (32A) and a second end (38B) arranged between the first opening (32A) and the gate electrode (24) in plan view, and the second end (38B) is located on the first extension (28).

[Clause 14]

The nitride semiconductor device according to clause 13, in which the second end (38B) of the first insulation layer (38) and the ridge (26) of the gate layer (22) are separated by a distance greater than or equal to 50 nm in plan view.

[Clause 15]

The nitride semiconductor device according to clause 8, in which a portion of the source field plate (36B) directly covers a portion of the first insulation layer (38), and the source field plate (36B) includes an end (36C) arranged on the first insulation layer (38).

[Clause 16]

The nitride semiconductor device according to any one of clauses 1 to 11, in which the first insulation layer (302) includes a first end (302A) arranged adjacent to the drain electrode (34) in the first opening (32A) and a second end (302B) arranged on the gate electrode (24).

[Clause 17]

A nitride semiconductor device, including:
an electron transit layer (16) composed of a nitride semiconductor;
an electron supply layer (18) formed on the electron transit layer (16) and composed of a nitride semiconductor having a band gap that is larger than that of the electron transit layer (16);
a gate layer (22) formed on a portion of the electron supply layer (18) and composed of a nitride semiconductor including an acceptor impurity;
a gate electrode (24) formed on the gate layer (22);
a passivation layer (502) covering the electron supply layer (18), the gate layer (22), and the gate electrode (24) and including a first opening (502A) and a second opening (502B);
a drain electrode (34) in contact with the electron supply layer through the first opening (502A); and
a source electrode (36) in contact with the electron supply layer through the second opening (502B), in which
the gate layer (22) is arranged between the first opening (502A) and the second opening (502B),
the passivation layer (502) includes
   a first part (504) formed on at least a portion of the electron supply layer (18) located between the first opening (502A) and the gate layer (22) in plan view, and
   a second part (506) formed on the electron supply layer (18) located between the second opening (502B) and the gate layer (22) in plan view, and the second part (506) is smaller in thickness than the first part (504).

[Clause 18]

The nitride semiconductor device according to clause 17, in which the first part (504) and the second part (506) of the passivation layer (502) are composed of different insulation layers.

[Clause 19]

The nitride semiconductor device according to any one of clauses 1 to 18, in which a maximum rating of gate-source voltage is greater than or equal to 8 V during application of a positive bias, and a maximum rating of gate-source voltage is greater than or equal to 4 V during application of a negative bias.

[Clause 20]

The nitride semiconductor device according to any one of clauses 1 to 19, in which
the electron transit layer (16) is GaN,
the electron supply layer (18) is AlₓGa₁₋ₓN, where 0.2<x<0.3, and
the gate layer (22) is GaN doped with at least one of Mg and Zn.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A nitride semiconductor device, comprising:
an electron transit layer composed of a nitride semiconductor;
an electron supply layer formed on the electron transit layer and composed of a nitride semiconductor having a band gap that is larger than that of the electron transit layer;
a gate layer formed on a portion of the electron supply layer and composed of a nitride semiconductor including an acceptor impurity;
a gate electrode formed on the gate layer;
a passivation layer covering the electron supply layer, the gate layer, and the gate electrode and including a first opening and a second opening;
a drain electrode in contact with the electron supply layer through the first opening; and
a source electrode in contact with the electron supply layer through the second opening, wherein
the gate layer is arranged between the first opening and the second opening,
the passivation layer includes
a first insulation layer formed on at least a portion of the electron supply layer located between the first opening and the gate layer in plan view, and
a second insulation layer formed on the electron supply layer located between the second opening and the gate layer in plan view and covering the gate layer and the gate electrode, and
the second insulation layer is formed of a material having a smaller Young's modulus than a material forming the first insulation layer.

2. The nitride semiconductor device according to claim 1, wherein a portion of the second insulation layer is formed on at least a portion of the first insulation layer.

3. The nitride semiconductor device according to claim 1, wherein
the first insulation layer includes SiN, and
the second insulation layer includes one of SiON and SiO₂.

4. The nitride semiconductor device according to claim 1, wherein
the source electrode includes a source contact filling the second opening and a source field plate covering the passivation layer, and
the source field plate includes an end located between the gate electrode and the first opening in plan view.

5. The nitride semiconductor device according to claim 1, wherein the gate layer includes
a ridge including an upper surface on which the gate electrode is formed, and
a first extension extending from the ridge toward the first opening in plan view and being smaller in thickness than the ridge.

6. The nitride semiconductor device according to claim 5, wherein the gate layer further includes a second extension extending from the ridge toward the second opening in plan view and being smaller in thickness than the ridge.

7. The nitride semiconductor device according to claim 6, wherein
the ridge has a thickness greater than 100 nm,
each of the first extension and the second extension has a thickness in a range of 5 nm to 100 nm, and
the electron supply layer has a thickness greater than or equal to 8 nm.

8. The nitride semiconductor device according to claim 5, wherein a portion of the second insulation layer is formed on at least a portion of the first extension.

9. The nitride semiconductor device according to claim 5, wherein
the first insulation layer includes a first end arranged adjacent to the drain electrode in the first opening and a second end arranged between the first opening and the gate electrode in plan view, and
the second end is located on the first extension.

10. The nitride semiconductor device according to claim 9, wherein the second end of the first insulation layer and the ridge of the gate layer are separated by a distance greater than or equal to 50 nm in plan view.

11. The nitride semiconductor device according to claim 4, wherein
a portion of the source field plate directly covers a portion of the first insulation layer, and
the source field plate includes an end arranged on the first insulation layer.

12. The nitride semiconductor device according to claim 1, wherein the first insulation layer includes a first end arranged adjacent to the drain electrode in the first opening and a second end arranged on the gate electrode.

13. A nitride semiconductor device, comprising:
an electron transit layer composed of a nitride semiconductor;
an electron supply layer formed on the electron transit layer and composed of a nitride semiconductor having a band gap that is larger than that of the electron transit layer;
a gate layer formed on a portion of the electron supply layer and composed of a nitride semiconductor including an acceptor impurity;
a gate electrode formed on the gate layer;
a passivation layer covering the electron supply layer, the gate layer, and the gate electrode and including a first opening and a second opening;
a drain electrode in contact with the electron supply layer through the first opening; and
a source electrode in contact with the electron supply layer through the second opening, wherein
the gate layer is arranged between the first opening and the second opening,
the passivation layer includes
a first part formed on at least a portion of the electron supply layer located between the first opening and the gate layer in plan view, and
a second part formed on the electron supply layer located between the second opening and the gate layer in plan view, and
the second part is smaller in thickness than the first part.

14. The nitride semiconductor device according to claim 1, wherein
a maximum rating of gate-source voltage is greater than or equal to 8 V during application of a positive bias, and
a maximum rating of gate-source voltage is greater than or equal to 4 V during application of a negative bias.

15. The nitride semiconductor device according to claim 1, wherein
the electron transit layer is GaN,
the electron supply layer is AlₓGa₁₋ₓN, where 0.2<x<0.3, and
the gate layer is GaN doped with at least one of Mg and Zn.
